(19) United States
(12) Patent Application Publication
(10) Pub. No.: US 2025/0062213 A1
(43) Pub. Date: Feb. 20, 2025

(54) SEMICONDUCTOR PACKAGE AND METHOD OF MANUFACTURING THE SEMICONDUCTOR PACKAGE

(71) Applicant: Samsung Electronics Co., Ltd., Suwon-si (KR)

(72) Inventors: Gyuho Kang, Suwon-si (KR); Hyungjun Park, Suwon-si (KR); Kwangok Jeong, Suwon-si (KR); Juil Choi, Suwon-si (KR); Taeoh Ha, Suwon-si (KR); Hongseo Heo, Suwon-si (KR)

(21) Appl. No.: 18/731,988

(22) Filed: Jun. 3, 2024

(30) Foreign Application Priority Data
Aug. 16, 2023 (KR) 10-2023-0106875

(51) Int. Cl. H01L 23/498; H01L 21/48; H01L 23/00

(52) U.S. Cl. CPC H01L 23/49838; H01L 23/49833; H01L 23/49866; H01L 24/08; H01L 24/16; H01L 24/32; H01L 24/73; H01L 21/486; H01L 2224/08225; H01L 2224/16225; H01L 2224/32225; H01L 2224/73204; H01L 2924/1815

(57) ABSTRACT

A semiconductor package includes a lower redistribution wiring layer that includes first redistribution wirings, a protective layer that defines openings, and bonding pads that are on the protective layer and are electrically connected to the first redistribution wirings through the openings; conductive bumps that are on first bonding pads of the bonding pads; and a semiconductor chip on the first bonding pads, where each of the bonding pads includes: a conductive pillar in a respective opening of the openings of the protective layer, where the conductive pillar includes a first diameter; and a pad pattern that is on the protective layer and an upper surface of the conductive pillar, where the pad pattern includes a second diameter that is greater than the first diameter.

### CROSS-REFERENCE TO RELATED APPLICATION

This application claims priority under 35 U.S.C. § 119 to Korean Patent Application No. 10-2023-0106875, filed on Aug. 16, 2023 in the Korean Intellectual Property Office (KIPO), the contents of which are herein incorporated by reference in their entirety.

### TECHNICAL FIELD

Example embodiments relate to a semiconductor package and a method of manufacturing the semiconductor package. More particularly, example embodiments relate to a fan out package and a method of manufacturing the same.

### BACKGROUND

In manufacturing a fan-out package, conductive bumps disposed on chip pads of a semiconductor chip may be respectively bonded to bonding pads on a lower redistribution wiring layer. The bonding pad may include a copper plating pattern formed in a via hole of an overlying passivation layer that exposes an uppermost redistribution wiring, and a nickel plating pattern and a gold plating pattern sequentially formed on the copper plating pattern. In the structure of the multi-layer bonding pad, a side surface of the copper plating pattern may be exposed to the outside, so there may be a problem in that the side surface of the copper plating pattern is etched together during a subsequent seed layer etching process or rework etching process. Additionally, since dimples are formed at an upper surface of the bonding pad due to the via hole, voids may occur between the bonding pad and the conductive bump bonded to the bonding pad.

### SUMMARY

Example embodiments provide a semiconductor package including bonding pads with improved reliability.

Example embodiments provide a method of manufacturing the semiconductor package.

According to example embodiments, a semiconductor package includes a lower redistribution wiring layer that includes first redistribution wirings, a protective layer that defines openings, and bonding pads that are on the protective layer and are electrically connected to the first redistribution wirings through the openings; conductive bumps that are on first bonding pads of the bonding pads; and a semiconductor chip on the first bonding pads, where each of the bonding pads includes: a conductive pillar in a respective opening of the openings of the protective layer, where the conductive pillar includes a first diameter; and a pad pattern that is on the protective layer and an upper surface of the conductive pillar, where the pad pattern includes a second diameter that is greater than the first diameter.

According to example embodiments, a semiconductor package includes a lower redistribution wiring layer that includes: a first region and a second region that at least partially surrounds the first region, first redistribution wirings, and a protective layer that defines first openings; a plurality of first bonding pads that are in the first region, on the protective layer, and electrically connected to the first redistribution wirings through the first openings; and a semiconductor chip that is on the first region of the lower redistribution wiring layer and electrically connected to the first bonding pads, where the semiconductor chip includes chip pads that face the lower redistribution wiring layer, where each of the first bonding pads includes: a conductive pillar in a respective first opening of the first openings of the protective layer; and a pad pattern that is on the protective layer and a portion of the conductive pillar.

According to example embodiments, a semiconductor package includes a redistribution wiring layer that includes redistribution wirings, a protective layer that defines openings, and bonding pads that are on the protective layer and are electrically connected to the redistribution wirings through the openings; conductive bumps on the bonding pads; and a first semiconductor device and a second semiconductor device that are spaced apart from each other on the redistribution wiring layer and are on the conductive bumps, where each of the bonding pads includes a conductive pillar in a respective opening of the openings of the protective layer, the conductive pillar including a first diameter; and a pad pattern that is on the protective layer and an upper surface of the conductive pillar, where the pad pattern includes a second diameter that is greater than the first diameter.

According to example embodiments, in a method of manufacturing a semiconductor package, a plurality of lower insulating layers having first redistribution wirings therein is formed, the plurality of lower insulating layers having a first region and a second region. A plurality of bonding pads is formed on the uppermost redistribution wirings among the first redistribution wirings, each of the plurality of bonding pads including a conductive pillar on the uppermost redistribution wiring and having a first diameter and a plating pattern covering an upper surface of the conductive pillar and having a second diameter greater than the first diameter. A semiconductor chip is mounted on the plurality of bonding pads disposed in the first region and electrically connected to the first redistribution wirings. A plurality of vertical conductive structures is formed on the plurality of bonding pads disposed in the second region. A molding member is formed on the lower redistribution wiring layer to cover the semiconductor chip and the plurality of vertical conductive structures. An upper redistribution wiring layer is formed on an upper surface of the molding member, the upper redistribution wiring layer having second redistribution wirings that are electrically connected to the conductive structures.

According to example embodiments, a semiconductor package as a fan-out wafer level package may include a lower redistribution wiring layer, a semiconductor chip disposed on the lower redistribution wiring layer, a molding member covering or overlapping at least a portion of the semiconductor chip on an upper surface of the lower redistribution wiring layer, a plurality of vertical conductive structures penetrating or extending into the molding member, and an upper redistribution wiring layer disposed on an upper surface of the molding member.

The lower redistribution wiring layer may include first redistribution wirings, a protective layer defining openings that expose at least portions of uppermost redistribution wirings among the first redistribution wirings, and upper bonding pads provided on the protective layer and electrically connected to the uppermost redistribution wirings through the openings.

Each of the upper bonding pads may include a conductive pillar provided in the opening of the protective layer and a pad pattern covering or overlapping an upper surface of the conductive pillar on the protective layer. The pad pattern may be provided on the protective layer to at least partially surround an upper portion of the conductive pillar that protrudes or extends from the opening of the protective layer.

Since the pad pattern surrounds the protruding upper portion of the conductive pillar including copper (Cu), the pad pattern may be formed to have a flat or slightly convex upper surface. Accordingly, when a seed layer under the pad pattern is removed or wet etch rework is performed, a side surface of the conductive pillar may be prevented or inhibited from being etched. Further, it may be possible to prevent or inhibit voids from occurring between the pad pattern of the upper bonding pad and a conductive bump or the vertical conductive structure bonded to the pad pattern of the upper bonding pad.

### BRIEF DESCRIPTION OF THE DRAWINGS

Example embodiments will be more clearly understood from the following detailed description taken in conjunction with the accompanying drawings. FIGS. 1 to 34 represent non-limiting, example embodiments as described herein.

FIG. 1 is a cross-sectional view illustrating a semiconductor package in accordance with example embodiments.

FIG. 2 is an enlarged cross-sectional view illustrating portion ‘A’ in FIG. 1.

FIG. 3 is a plan view illustrating first upper redistribution wirings and a heat dissipation pattern provided on an upper surface of a molding member of FIG. 1.

FIGS. 4, 5, 6, 7, 8, 9, 10, 11, 12, 13, 14, 15, 16, 17, 18, 19, 20, 21, 22, and 23 are views illustrating a method of manufacturing a semiconductor package in accordance with example embodiments.

FIG. 24 is a cross-sectional view illustrating a semiconductor package in accordance with example embodiments.

FIG. 25 is an enlarged cross-sectional view illustrating portion ‘I’ in FIG. 24.

FIG. 26 is an enlarged cross-sectional view illustrating portion ‘J’ in FIG. 24.

FIGS. 27, 28, 29, 30, and 31 are cross-sectional views illustrating a method of manufacturing a semiconductor package in accordance with example embodiments.

FIG. 32 is a cross-sectional view illustrating a semiconductor package in accordance with example embodiments.

FIG. 33 is a cross-sectional view illustrating a semiconductor package in accordance with example embodiments.

FIG. 34 is an enlarged cross-sectional view illustrating portion ‘L’ in FIG. 33.

### DETAILED DESCRIPTION OF EXAMPLE EMBODIMENTS

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the phrase “at least one of A, B, and C” refers to a logical (A OR B OR C) using a non-exclusive logical OR, and should not be construed to mean “at least one of A, at least one of B and at least one of C.” As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. As used herein, “an element A is at a same level as element B” refers to at least one surface of element A that is coplanar with at least one surface of element B. As used herein, “an element A is at a lower level than element B” refers to at least one surface of element A that extends from a reference object by a smaller distance than element B extends from the same reference object. As used herein, “an element A is at a higher level than element B” refers to at least one surface of element A that extends from a reference object by a greater distance than element B extends from the same reference object. The term “connected” may be used herein to refer to a physical and/or electrical connection and may refer to a direct or indirect physical and/or electrical connection. Components or layers described with reference to “overlap” in a particular direction may be at least partially obstructed by one another when viewed along a line extending in the particular direction or in a plane perpendicular to the particular direction.

Hereinafter, example embodiments will be explained in detail with reference to the accompanying drawings.

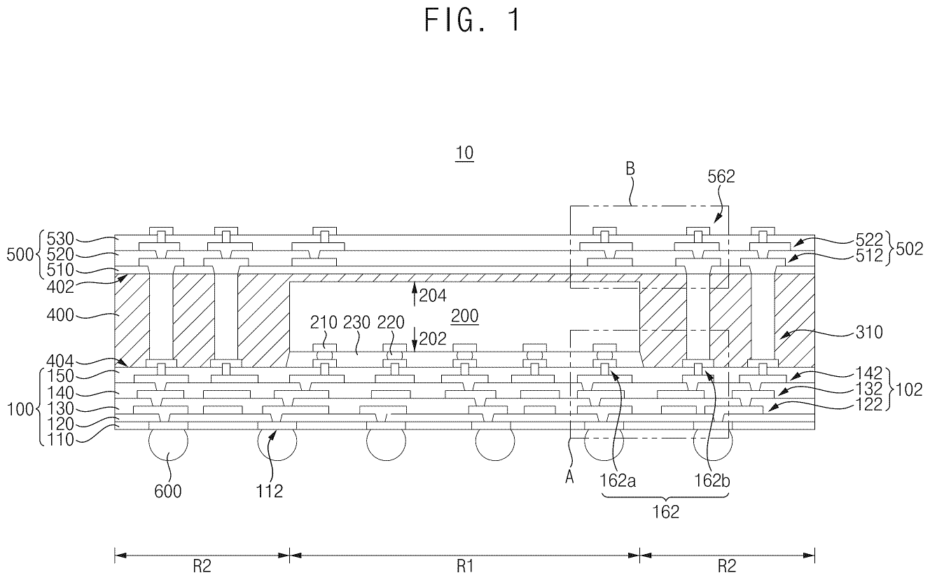

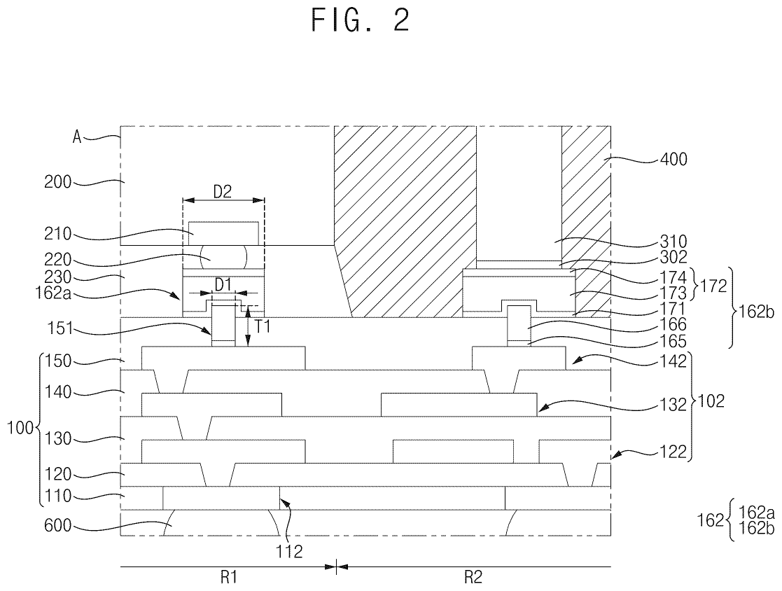

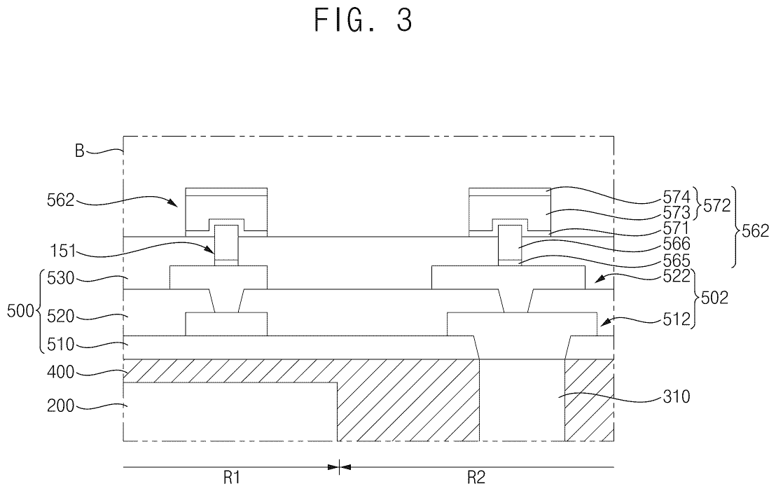

FIG. 1 is a cross-sectional view illustrating a semiconductor package in accordance with example embodiments. FIG. 2 is an enlarged cross-sectional view illustrating portion ‘A’ in FIG. 1. FIG. 3 is an enlarged cross-sectional view illustrating portion ‘B’ in FIG. 1.

Referring to FIGS. 1 to 3, a semiconductor package 10 may include a lower redistribution wiring layer 100, a semiconductor chip 200 disposed on the lower redistribution wiring layer 100, a molding member 400 on an upper surface of the lower redistribution wiring layer 100 and covering or overlapping at least a portion of the semiconductor chip 200, an upper redistribution wiring layer 500 disposed on an upper surface 402 of the molding member 400, and a plurality of vertical conductive structures 310 penetrating or extending into the molding member 400 and electrically connecting the lower redistribution wiring layer 100 and the upper redistribution wiring layer 500. In addition, the semiconductor package 10 may further include external connection members 600 disposed on an outer surface of the lower redistribution wiring layer 100.

In example embodiments, the semiconductor package 10 may be a fan out package in which the lower redistribution wiring layer 100 extends to a lower surface of the molding member 400 to cover or overlap an outer side surface of the semiconductor chip 200. The lower redistribution wiring layer 100 may be formed by a wafer level redistribution wiring process. Additionally, the semiconductor package 10 may be provided as a unit package on which a second package is stacked.

Additionally, the semiconductor package 10 may be provided as a System In Package (SIP). For example, one or more semiconductor chips may be disposed on the lower redistribution wiring layer 100. The semiconductor chips may include a logic chip including a logic circuit and/or a memory chip. The logic chip may be a controller that controls memory chips. The memory chip includes various types of memory circuits such as DRAM, SRAM, flash, PRAM, ReRAM, FeRAM, or MRAM.

In example embodiments, the lower redistribution wiring layer 100 may have first redistribution wirings 102. The semiconductor chip 200 may be disposed on the lower redistribution wiring layer 100 to be electrically connected to the first redistribution wirings 102. The lower redistribution wiring layer 100 may be provided on a front surface 202 of the semiconductor chip 200 to serve as a front redistribution wiring layer. Accordingly, the lower redistribution wiring layer 100 may be a front redistribution wiring layer (FRDL) of the fan out package.

In particular, the lower redistribution wiring layer 100 may include a plurality of first, second, third, fourth and fifth lower insulating layers 110, 120, 130, 140 and 150 and the first redistribution wirings 102 provided in the first, second, third, fourth and fifth lower insulating layers. The first redistribution wirings 102 may include first, second and third lower redistribution wirings 122, 132 and 142.

The first, second, third, fourth and fifth lower insulating layers may include a polymer or a dielectric layer. For example, the first, second, third, fourth and fifth lower insulating layers may include a photosensitive insulating layer, such as a photo imagable dielectric (PID). The first, second, third, fourth and fifth lower insulating layers may be formed by a vapor deposition process, a spin coating process, etc. The first redistribution wirings may include aluminum (Al), copper (Cu), tin (Sn), nickel (Ni), gold (Au), platinum (Pt), or an alloy thereof. The first redistribution wiring may be formed by a plating process, an electroless plating process, a vapor deposition process, etc.

In particular, a lower bonding pad 112 may be provided in the first lower insulating layer 110. The lower bonding pad 112 may be a bump pad. The bump pad may include a solder pad or pillar pad. For example, the lower bonding pad may include copper (Cu), aluminum (Al), tin (Sn), nickel (Ni), gold (Au), platinum (Pt), or an alloy thereof.

The second lower insulating layer 120 may be formed on the first lower insulating layer 110 and the first lower redistribution wiring 122 may be formed on the second lower insulating layer 120. The first lower redistribution wiring 122 may be electrically connected to the lower bonding pad through a first opening formed in the second lower insulating layer 120.

The third lower insulating layer 130 may be formed on the second lower insulating layer 120 and the second lower redistribution wiring 132 may be formed on the third lower insulating layer 130. The second lower redistribution wiring 132 may be electrically connected to the first lower redistribution wiring 122 through a second opening formed in the third lower insulating layer 130.

The fourth lower insulating layer 140 may be formed on the third lower insulating layer 130 and the third lower redistribution wiring 142 may be formed on the fourth lower insulating layer 140. The third lower redistribution wiring 142 may be electrically connected to the second lower redistribution wiring 132 through a third opening formed in the fourth lower insulating layer 140.

The fifth lower insulating layer 150, which may be a solder resist layer, may be formed on the fourth lower insulating layer 140 and may have openings 151 that expose portions of the third lower redistribution wirings 142. The fifth lower insulating layer 150 may function as a passivation layer. For example, the fifth lower insulating layer 150 may include an insulating material such as a photosensitive insulating material (PID). Upper bonding pads 162 may be disposed on the exposed portions of the third lower redistribution wirings 142, which serve as uppermost redistribution wirings.

The numbers and arrangements of the lower insulating layers and the lower redistribution wirings of the lower redistribution wiring layer are provided as examples, and it will be appreciated that the present disclosure is not limited thereto.

In example embodiments, when viewed in plan view, the lower redistribution wiring layer 100 may include a first region R1 as a chip mounting region overlapping with the semiconductor chip 200 to be mounted on the lower redistribution wiring layer 100, and a second region R2 as a connector region surrounding the first region R1. The second region R2 may be a fan-out region outside the region where the semiconductor chip is disposed.

The upper bonding pads 162 may be exposed from an upper surface of the lower redistribution wiring layer 100. The upper bonding pads 162 may include first bonding pads 162a (e.g., chip connection bonding pads) formed on the uppermost first redistribution wirings 142 located in the first region R1, and second bonding pads 162b as conductive structure connection bonding pads formed on the uppermost first redistribution wirings 142 located in the second region R2.

As illustrated in FIG. 2, each of the upper bonding pads 162 may include a conductive pillar 166 and a pad pattern 172 stacked on the conductive pillar 166. The conductive pillar 166 may extend upward on the uppermost redistribution wiring 142 among the first redistribution wirings 102. The fifth lower insulating layer 150 may at least partially cover or overlap a side surface of the conductive pillar 166. The conductive pillar 166 may be provided in the opening 151 of the fifth lower insulating layer 150 on the uppermost redistribution wiring 142. The conductive pillar 166 may completely fill or be in the opening 151 of the fifth lower insulating layer 150 on the uppermost redistribution wiring 142. An upper portion of the conductive pillar 166 may protrude or extend from the opening 151 of the fifth lower insulating layer 150.

The pad pattern 172 may be provided on the fifth lower insulating layer 150 to at least partially surround the upper portion of the conductive pillar 166 that protrudes or extends from the opening 151 of the fifth lower insulating layer 150. Since the pad pattern 172 surrounds the protruding upper portion of the conductive pillar 166, the pad pattern 172 may have a flat upper surface. The upper bonding pad 162 may further include a second seed layer pattern 171 that conformally covers or overlaps the upper portion of the conductive pillar 166 that is exposed from the opening 151 on the fifth lower insulating layer 150, and the pad pattern 172 may be formed on the second seed layer pattern 171. The pad pattern 172 may include a first plating pattern 173 and a second plating pattern 174 that are sequentially stacked.

For example, the conductive pillar 166 may have a first diameter D1. The first diameter D1 may be in a range of about 5 μm to 50 μm. The first thickness T1 of the conductive pillar 166 may be within a range of 0.5 μm to 5 μm. The pad pattern 172 may have a second diameter D2 greater than the first diameter D1. The second diameter D1 may be in a range of about 10 μm to 80 μm. A thickness of the first plating pattern 173 may be within a range of about 2 μm to 8 μm. A thickness of the second plating pattern 174 may be within a range of about 0.2 μm to 1 μm. The first plating pattern 173 may include nickel (Ni). The second plating pattern 174 may include gold (Au).

In example embodiments, the semiconductor chip 200 may have a plurality of chip pads 210 on a first surface 202, that is, an active surface thereof. The semiconductor chip 200 may be mounted on the lower redistribution wiring layer 100 such that the first surface on which the chip pads 210 are formed faces the lower redistribution wiring layer 100.

The semiconductor chip 200 may be mounted on the lower redistribution wiring layer 100 by a flip chip bonding method. The semiconductor chip 200 may be mounted on the lower redistribution wiring layer 100 via conductive bumps 220. The conductive bump 220 may be disposed between the first bonding pad 162a on the third lower redistribution wiring 142 of the lower redistribution wiring layer 100 and the chip pad 210 of the semiconductor chip 200 to electrically connect the semiconductor chip 200 and the first redistribution wiring 102. For example, the conductive bump 220 may include a pillar bump formed on the chip pad 210 of the semiconductor chip 200 and a solder bump formed on the pillar bump. Alternatively, the conductive bump 220 may include a solder bump formed on the chip pad 210 of the semiconductor chip 200. An underfill member 230 may be disposed between the semiconductor chip 200 and the lower redistribution wiring layer 100.

The semiconductor chip may be a logic chip including a logic circuit. The logic chip may be a controller that controls memory chips. The semiconductor chip may be a processor chip such as an ASIC or an application processor AP serving as a host such as a CPU, GPU, or SOC.

Although only a few chip pads are illustrated in the figures, the structures and arrangements of the chip pads are provided as examples, and it will be understood that the present disclosure is not limited thereto. Additionally, although only one semiconductor chip is illustrated, it may not be limited thereto, and a plurality of semiconductor chips may be stacked on the lower redistribution wiring layer.

In example embodiments, the molding member 400 may cover or overlap at least a portion of the semiconductor chip 200 on the upper surface of the lower redistribution wiring layer 100. The molding member 400 may include a first molding portion covering or overlapping an upper surface 204 of the semiconductor chip 200 and a second sealing portion covering or overlapping the upper surface of the lower redistribution wiring layer 100 that at least partially surround the semiconductor chip 200.

For example, the molding member 400 may include an epoxy mold compound (EMC). The molding member 400 may be formed by a molding process, a screen printing process, a lamination process, etc.

In example embodiments, a plurality of vertical conductive structures 310 may extend in a vertical direction to penetrate or extend into the molding member 400. The vertical conductive structure 310 may be formed on the second bonding pad 162b on the uppermost first redistribution wiring 142 located in the second region R2.

The vertical conductive structure 310 may be provided to penetrate or extend into the molding member 400 and may serve as an electrical connection path. The vertical conductive structure 310 may be a through mold via (TMV) formed to extend through the second sealing portion of the molding member 400. That is, the vertical conductive structures 310 may be provided in the fan-out region R2 outside an area where the semiconductor chip 200 is disposed, to electrically connect the lower redistribution wiring layer 100 and the upper redistribution wiring layer 500. For example, the vertical conductive structure 310 may include copper (Cu), aluminum (Al), tin (Sn), nickel (Ni), gold (Au), platinum (Pt), or alloys thereof.

In example embodiments, the upper redistribution wiring layer 500 may be disposed on the molding member 400 and may include second redistribution wirings 502 electrically connected to the vertical conductive structure 310 respectively. The second redistribution wirings 502 may include upper redistribution wirings 512, 522 stacked in at least two layers. The second redistribution wirings 502 may be provided on the molding member 400 to serve as backside redistribution wirings. Accordingly, the upper redistribution wiring layer 500 may be a backside redistribution wiring layer (BRDL) of the fan out package.

The second redistribution wirings 502 may include first upper redistribution wirings 512 and second upper redistribution wirings 522 that are sequentially stacked. In this case, the first upper redistribution wiring 512 may correspond to a lowermost redistribution wiring among the second redistribution wirings, and the second upper redistribution wiring 522 may correspond to an uppermost redistribution wiring among the second redistribution wirings.

A first upper insulating layer 510 may be provided on the upper surface 402 of the molding member 400 and may have openings that expose upper portions of the vertical conductive structures 310. The second upper redistribution wirings 512 may be formed on the first upper insulating layer 510 and may be electrically connected to the upper portions of the vertical conductive structures 310 through the openings of the first upper insulating layer 510.

A second upper insulating layer 520 may be provided on the first upper insulating layer 510 and may have openings that expose the second upper redistribution wirings 512. The second upper redistribution wirings 522 may be formed on the second upper insulating layer 520 and at least portion of the second upper redistribution wirings 522 may be electrically connected to the first upper redistribution wirings 512 through the openings of the second upper insulating layer 520.

For example, the first and second upper insulating layers may include a polymer, a dielectric layer, etc. The first and second insulating layers may include a photosensitive insulating material such as PID or an insulating film such as ABF. The second redistribution wirings may include copper (Cu), aluminum (Al), tin (Sn), nickel (Ni), gold (Au), platinum (Pt), or an alloy thereof.

It will be understood that the number, size, and arrangement of the upper insulating layers and the upper redistribution wirings of the second redistribution wiring layer are provided as examples, and the present disclosure is not limited thereto.

As illustrated in FIG. 3, upper bonding pads 562 may be provided on the second upper redistribution wirings 522. A third upper insulating layer 530, which may be a protective layer, may be formed on the second upper insulating layer 520 and may have openings 531 that expose portions of the second upper redistribution wirings 522. For example, the third upper insulating layer 530 may include an insulating material, such as a photosensitive insulating material (PID). The upper bonding pads 562 may be disposed on the exposed portions of the second upper redistribution wirings 522 as uppermost redistribution wirings. The upper bonding pad 562 may have a structure substantially the same as the upper bonding pad 162 of the lower redistribution wiring layer 100.

In particular, each of the upper bonding pads 562 may include a conductive pillar 566 and a pad pattern 572 stacked on the conductive pillar 566. The conductive pillar 566 may be provided within the opening 531 of the third upper insulating layer 530 on the uppermost redistribution wiring 522. The conductive pillar 566 may completely fill or be in the opening 531 of the third upper insulating layer 530 on the uppermost redistribution wiring 522. An upper portion of the conductive pillar 566 may protrude or extend from the opening 531 of the third upper insulating layer 530.

The pad pattern 572 may be provided on the third upper insulating layer 530 to at least partially surround the upper portion of the conductive pillar 566 that protrudes or extends from the opening 531 of the third upper insulating layer 530. Since the pad pattern 572 surrounds the protruding upper portion of the conductive pillar 566, the pad pattern 572 may be formed to have a flat or slightly convex upper surface. The upper bonding pad 562 may further include a fourth seed layer pattern 571 that conformally covers or overlaps the upper portion of the conductive pillar 566 that is exposed from the opening 531 on the third upper insulating layer 530, and the pad pattern 572 may be formed on the fourth seed layer pattern 571. The pad pattern 572 may include a first plating pattern 573 and a second plating pattern 574 that are sequentially stacked.

For example, the conductive pillar 566 may include copper (Cu). The first plating pattern 573 may include nickel (Ni), and the second plating pattern 574 may include gold (Au). However, the materials of the conductive pillar, the first plating pattern, and the second plating pattern are not limited thereto, and may be determined in consideration of diffusion of intermetallic materials and wetting with a solder material during a soldering process.

In example embodiments, the external connection members 600 may be disposed on the lower bonding pads 112 on an outer surface of the lower redistribution wiring layer 100. For example, the external connection member 600 may include a solder ball. The solder ball may have a diameter of 300 μm to 500 μm. The semiconductor package 10 may be mounted on a module substrate (not illustrated) via the solder balls to form a memory module.

As mentioned above, the semiconductor package 10 as the fan-out wafer level package may include the lower redistribution wiring layer 100, the semiconductor chip 200 disposed on the lower redistribution wiring layer 100, the molding member 400 covering or overlapping at least a portion of the semiconductor chip 200 on the upper surface of the lower redistribution wiring layer 100, the plurality of vertical conductive structures 310 penetrating or extending into the molding member 400, and the upper redistribution wiring layer 500 disposed on the upper surface 402 of the molding member 400.

The lower redistribution wiring layer 100 may include the first redistribution wirings 102, the protective layer 150 having the openings 151 that expose at least portions of uppermost redistribution wirings 142 among the first redistribution wirings 102, and the upper bonding pads 162 provided on the protective layer 150 and electrically connected to the uppermost redistribution wirings 142 through the openings 151.

Each of the upper bonding pads 162 may include the conductive pillar 166 provided in the opening 151 of the protective layer 150 on the uppermost redistribution wiring 142 and the pad pattern 172 covering or overlapping the upper surface of the conductive pillar 166 on the protective layer 150. The upper portion of the conductive pillar 166 may protrude or extend from the opening 151 of the protective layer 150. The pad pattern 172 may be provided on the protective layer 150 to at least partially surround the upper portion of the conductive pillar 166 that protrudes from the opening 151 of the protective layer 150.

Since the pad pattern 172 surrounds the protruding upper portion of the conductive pillar 166 including copper (Cu), the pad pattern 172 may be formed to have a flat or slightly convex upper surface. Accordingly, when the seed layer under the pad pattern 172 is removed or wet etch rework is performed, the side surface of the conductive pillar 166 may be prevented or inhibited from being etched. Further, it may be possible to prevent or inhibit voids from occurring between the pad pattern 172 of the upper bonding pad 162 and the conductive bump 220 or the vertical conductive structure 310 bonded to the pad pattern 172 of the upper bonding pad 162.

Hereinafter, a method of manufacturing the semiconductor package of FIG. 1 will be described.

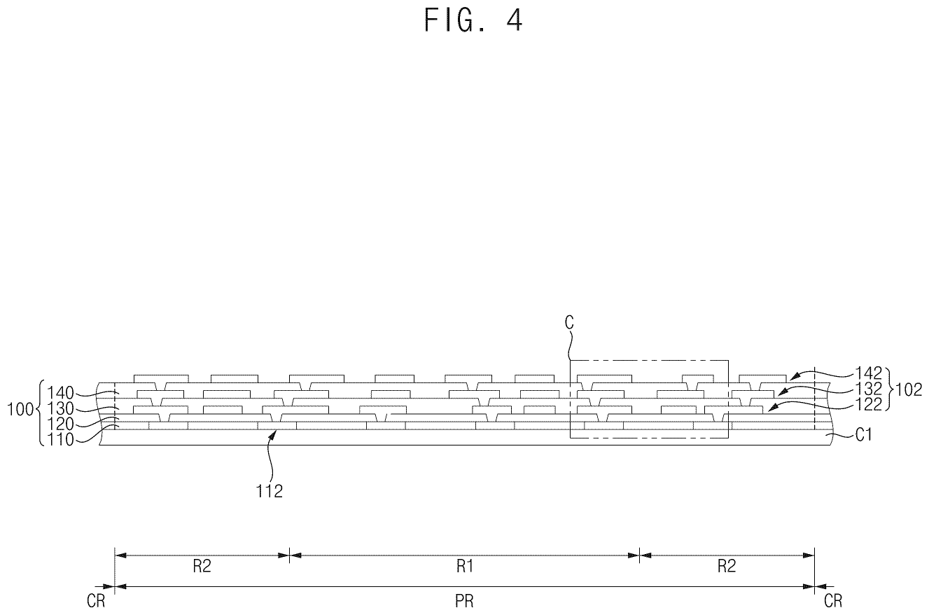

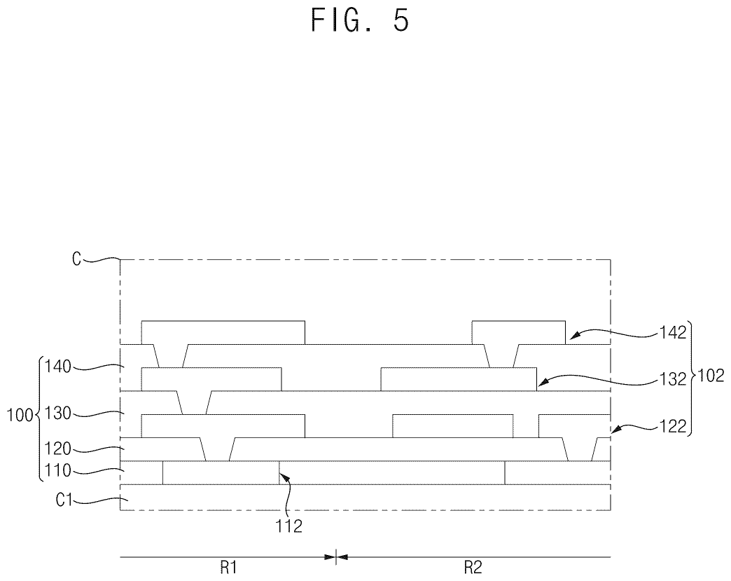

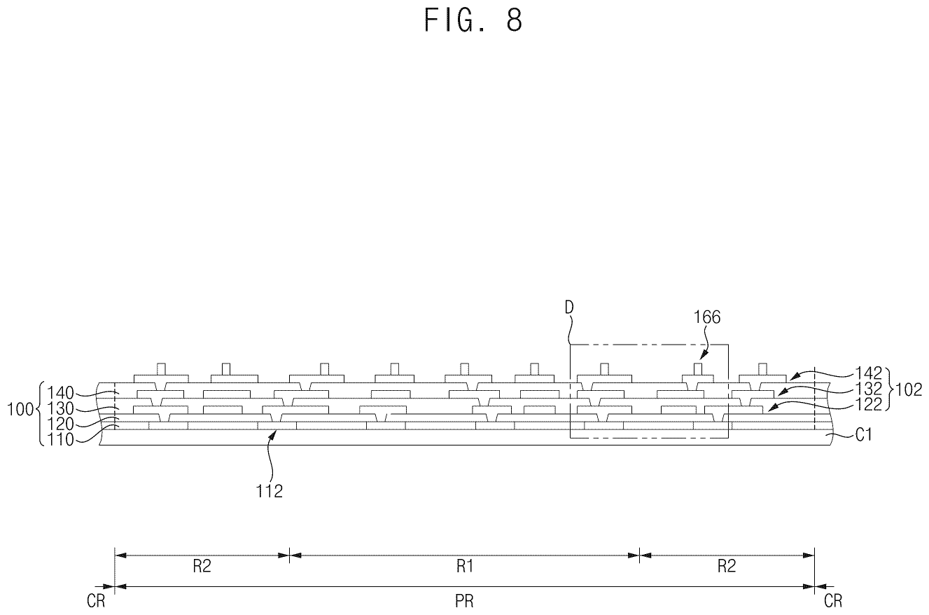

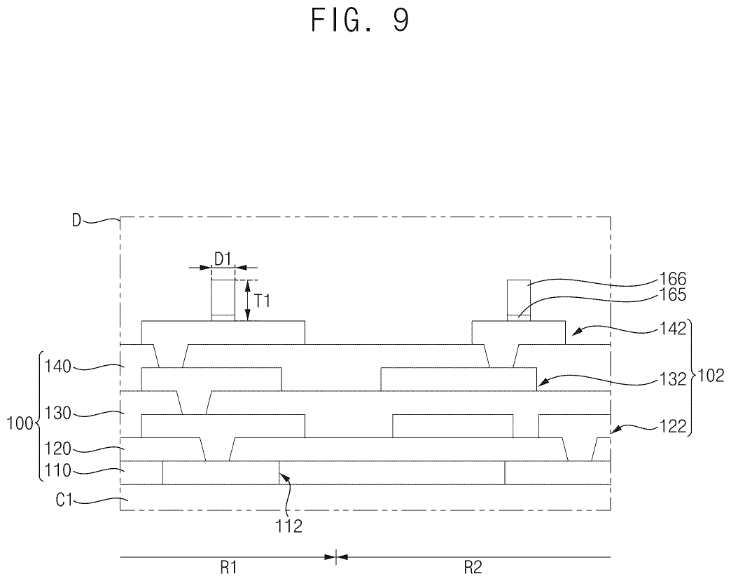

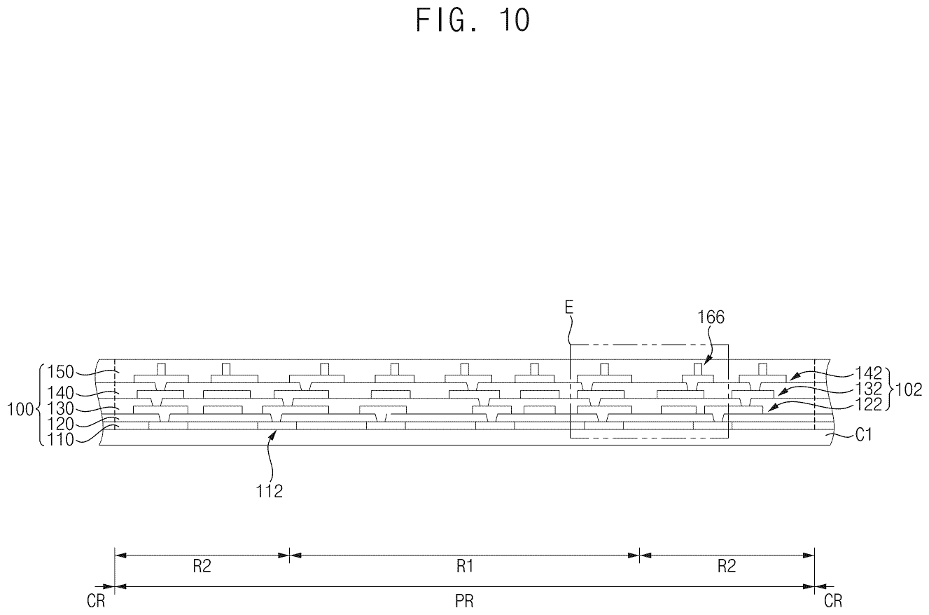

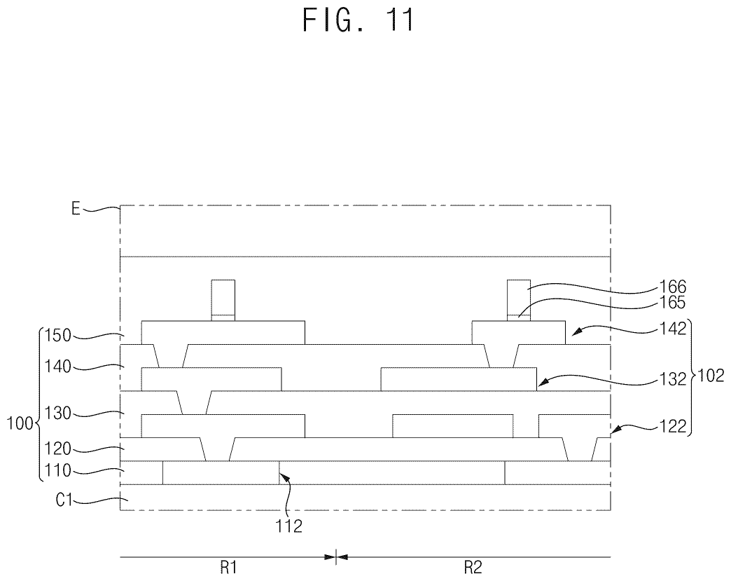

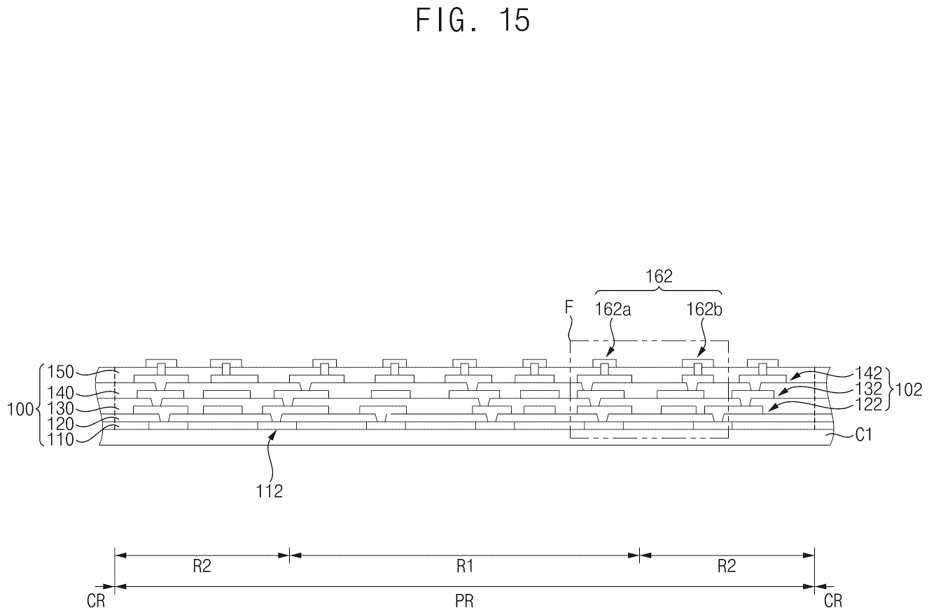

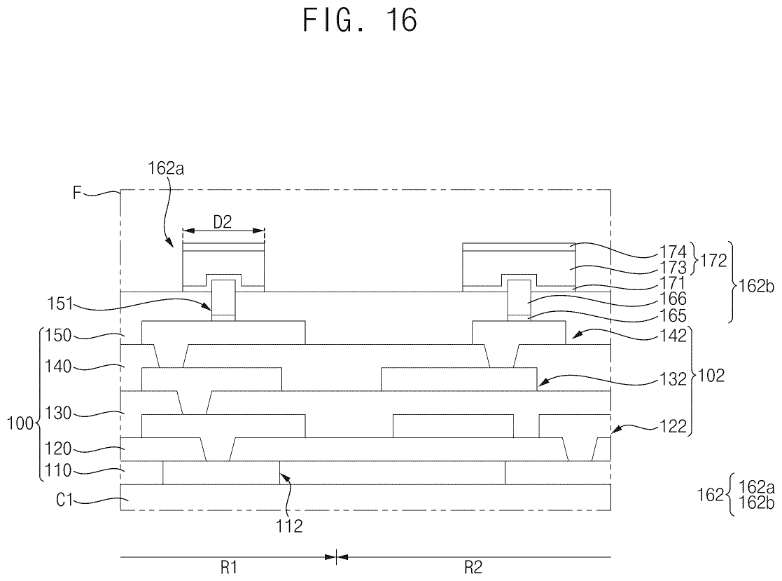

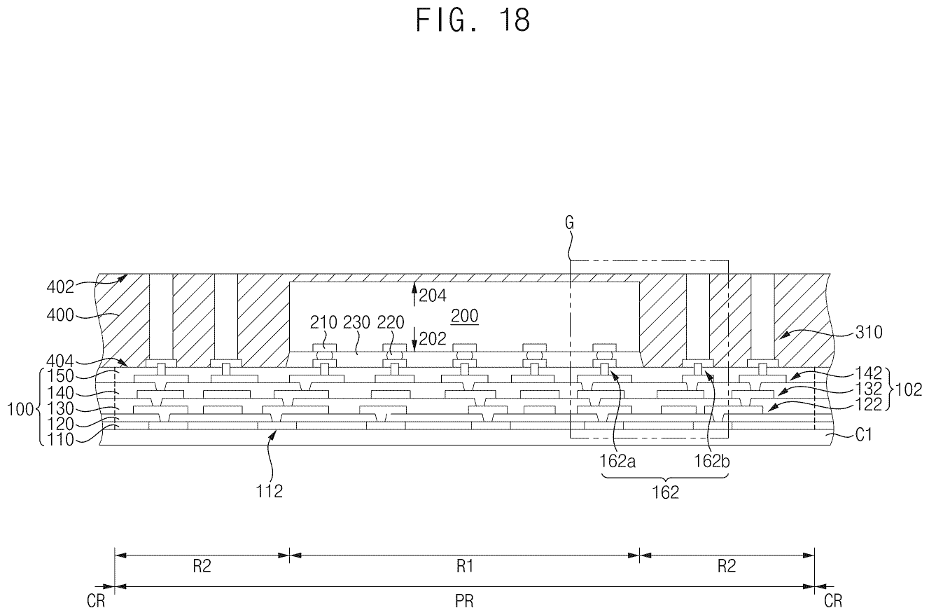

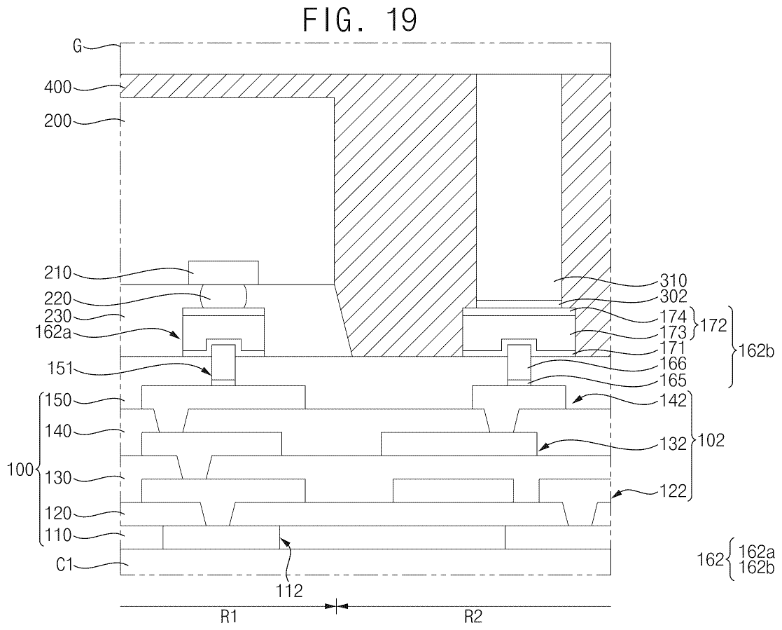

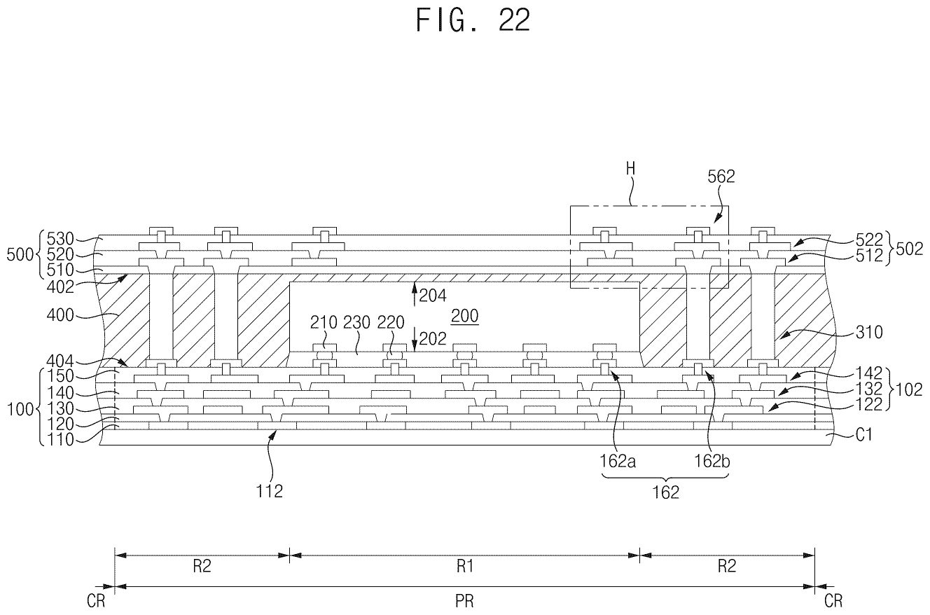

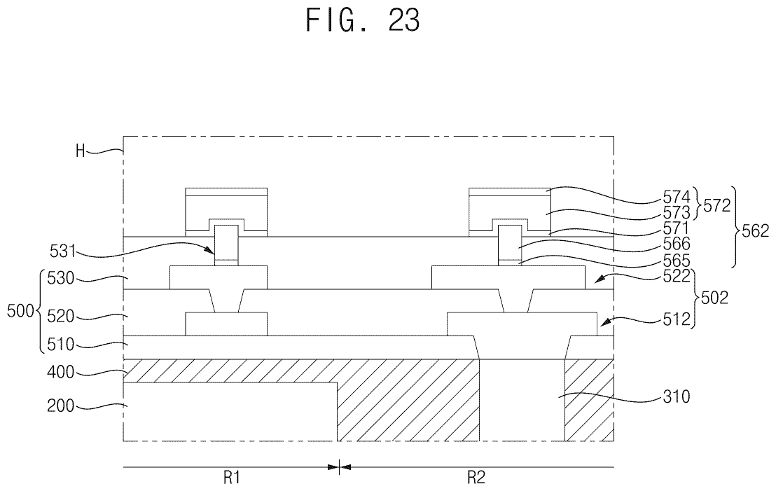

FIGS. 4 to 23 are views illustrating a method of manufacturing a semiconductor package in accordance with example embodiments. FIGS. 4, 8, 10, 15, 17, 18, 20, 21 and 22 are cross-sectional views illustrating a method of manufacturing a semiconductor package in accordance with example embodiments. FIGS. 5 to 7 are enlarged cross-sectional views illustrating portion ‘C’ in FIG. 4. FIG. 9 is an enlarged cross-sectional view illustrating portion ‘D’ in FIG. 8. FIGS. 11 to 14 are enlarged cross-sectional views illustrating portion ‘E’ in FIG. 10. FIG. 16 is an enlarged cross-sectional views illustrating portion ‘F’ in FIG. 15. FIG. 19 is an enlarged cross-sectional view illustrating portion ‘G’ in FIG. 18. FIG. 23 is an enlarged cross-sectional view illustrating portion ‘H’ in FIG. 22.

Referring to FIGS. 4 and 5, a lower redistribution wiring layer 100 having first redistribution wirings 102 may be formed on a carrier substrate C1.

In example embodiments, the carrier substrate C1 may include a wafer substrate as a base substrate for disposing a plurality of semiconductor chips on the lower redistribution wiring layer and forming a molding member covering or overlapping the plurality of semiconductor chips. The carrier substrate C1 may have a shape corresponding to a wafer on which a semiconductor process is performed. For example, the carrier substrate C1 may include a silicon substrate, a glass substrate, a non-metal or metal plate, etc.

The carrier substrate C1 may include a package region PR on which the semiconductor chip is mounted and a cutting region CR at least partially surrounding the package region PR. As will be described later, the lower redistribution wiring layer 100 and the molding member formed on the carrier substrate C1 may be cut along the cutting region CR that divides the plurality of package regions MR to be individualized.

In example embodiments, a first lower insulating layer 110 having lower bonding pads 112 formed therein may be formed on the carrier substrate C1. Although it is not illustrated in the figures, after a release film, a barrier metal layer, a seed layer and the first lower insulating layer are sequentially formed on the carrier substrate C1, the first lower insulating layer may be patterned to form openings that expose first bonding pad regions. Then, a plating process may be performed on the seed layer to form the lower bonding pads 112.

For example, the first lower insulating layer 110 may include a polymer or a dielectric layer. The first lower insulating layer 110 may include a photosensitive insulating material, such as PID or an insulating film such as ABF. The first lower insulating layer may be formed by a spin coating process, a vapor deposition process, etc.

The lower bonding pad 112 may be a bump pad. The bump pad may include a solder pad or pillar pad. For example, the lower bonding pad may include copper (Cu), aluminum (Al), tin (Sn), nickel (Ni), gold (Au), platinum (Pt), or an alloy thereof.

Then, after a second lower insulating layer 120 is formed on the carrier substrate C1 to cover or overlap the lower bonding pads 112, the second lower insulating layer 120 may be patterned to form first openings that expose the lower bonding pads 112.

For example, the second lower insulating layer 120 may include a polymer or a dielectric layer. The second lower insulating layer 120 may include a photosensitive insulating material, such as PID or an insulating film such as ABF. The second lower insulating layer may be formed by a spin coating process, a vapor deposition process, etc.

Then, first lower redistribution wirings 122 may be formed on the second lower insulating layer 120 to be electrically connected to the lower bonding pads 112 through the first openings, respectively.

For example, after a seed layer is formed on portions of the second lower insulating layer 120 and in the first opening, the seed layer may be patterned and an electroplating process may be performed to form the first lower redistribution wirings 122. Accordingly, at least portions of the first lower redistribution wirings 122 may directly contact the lower bonding pads 112 through the first openings of the second lower insulating layer 120. For example, the first lower redistribution wiring may include copper (Cu), aluminum (Al), tin (Sn), nickel (Ni), gold (Au), platinum (Pt), or an alloy thereof.

Similarly, after a third lower insulating layer 130 is formed on the second lower insulating layer 120 to cover or overlap the first lower redistribution wirings 122, the third lower insulating layer 130 may be patterned to form second openings that expose at least portions of the first lower redistribution wirings 122. Then, second lower redistribution wirings 132 may be formed on the third lower insulating layer 130 to directly contact the first lower redistribution wirings 122 through the second openings of the third lower insulating layer 130.

Then, after a fourth lower insulating layer 140 is formed on the third lower insulating layer 130 to cover or overlap the second lower redistribution wirings 132, the fourth lower insulating layer 140 may be patterned to form third openings that expose at least portions of the second lower redistribution wirings 132. Then, third lower redistribution wirings 142 may be formed on the fourth lower insulating layer 140 to directly contact the second lower redistribution wirings 132 through the third openings of the fourth lower insulating layer 140.

Thus, the lower redistribution wiring layer 100 having the first, second, third and fourth lower insulating layers 110, 120, 130 and 140 may be formed. The first redistribution wirings 102 may be provided in the first, second, third and fourth lower insulating layers 110, 120, 130 and 140. The lower redistribution wiring layer 100 may be a front redistribution wiring layer (FRDL) of a fan out package. The lower redistribution wiring layer 100 may include the first, second and third lower redistribution wirings 122, 132 and 142 stacked vertically in third layers. The lower bonding pads 112 may be exposed from a lower surface of the lower redistribution wiring layer 100. For example, a thickness of the first redistribution wiring layer 100 may be within a range of 5 μm to 50 μm.

When viewed in plan view, the lower redistribution wiring layer 100 may include a first region R1 as a chip mounting region overlapping with the semiconductor chip to be mounted on the lower redistribution wiring layer 100 as will be described later, and a second region R2 as a connector region surrounding the first region R1. The second region R2 may be a fan-out region outside the region where the semiconductor chip is disposed.

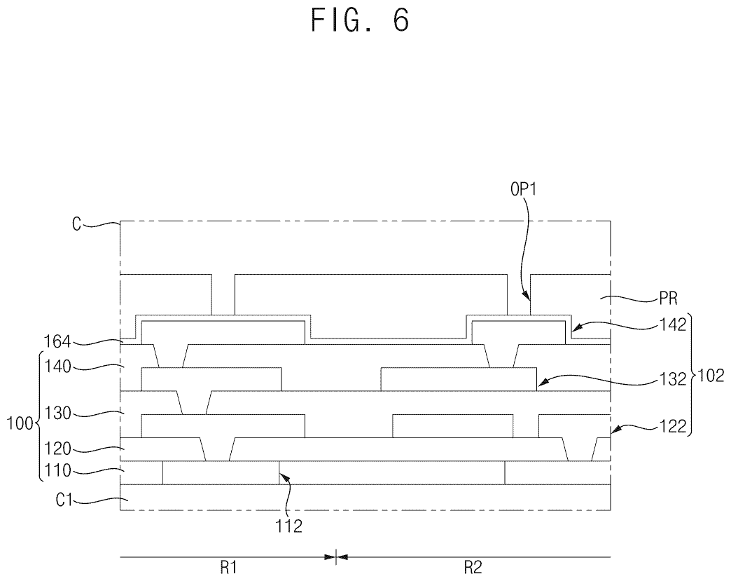

Referring to FIGS. 6 to 16, upper bonding pads 162 may be formed on the uppermost first redistribution wirings 142. The upper bonding pads 162 may include first bonding pads 162a as chip connection bonding pads formed on the uppermost first redistribution wirings 142 located in the first region R1, and second bonding pads 162b as conductive structure connection bonding pads formed on the uppermost first redistribution wirings 142 located in the second region R2.

As illustrated in FIG. 6, a first seed layer 164 may be formed on the fourth lower insulating layer 140, and a first photoresist pattern PR1 having first openings OP1 that expose conductive pillar regions may be formed on the first seed layer 164. The first openings may include first opening patterns that expose first conductive pillar regions in the first region R1 and second opening patterns that expose second conductive pillar regions in the second region R2.

For example, the first seed layer may include copper, gold, silver, aluminum, or an alloy thereof. The first seed layer may be formed by a physical vapor deposition process or the like. The first seed layer may have a thickness of about 500 Å to about 1,500 Å.

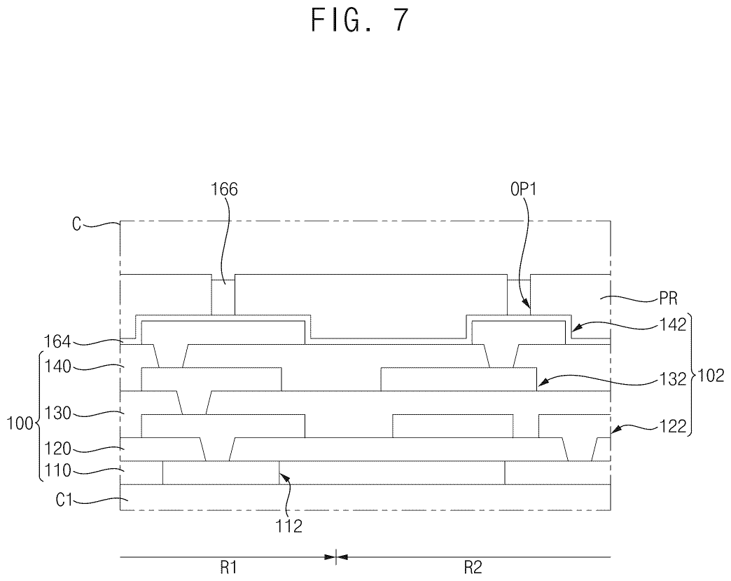

As illustrated in FIG. 7, an electrolytic plating process may be performed to form conductive pillars 166 in the first openings OP1 of the first photoresist pattern PR1. The conductive pillars 166 may include a metallic material. The conductive pillars 166 may include the same material as the third lower redistribution wiring 142. The conductive pillars may include copper (Cu).

As illustrated in FIGS. 8 and 9, the first photoresist pattern PR1 may be removed by a strip process. Accordingly, the conductive pillars 166 may extend upward on the uppermost first redistribution wirings 142 respectively. Then, an etching process may be performed to remove portions of the first seed layer 164 exposed by the conductive pillars 166 to form a first seed layer pattern 165.

For example, the conductive pillar 166 may have a first diameter D1. The first diameter D1 may be in a range of 5 μm to 50 μm. The first thickness T1 of the conductive pillar 166 may be within a range of 0.5 μm to 5 μm.

As illustrated in FIGS. 10 and 11, a fifth lower insulating layer 150 as a protective layer may be formed on the fourth lower insulating layer 140 to cover the third lower redistribution wirings 142 and the conductive pillars 166. For example, the fifth lower insulating layer 150 may include an insulating material such as a photosensitive insulating material (PID).

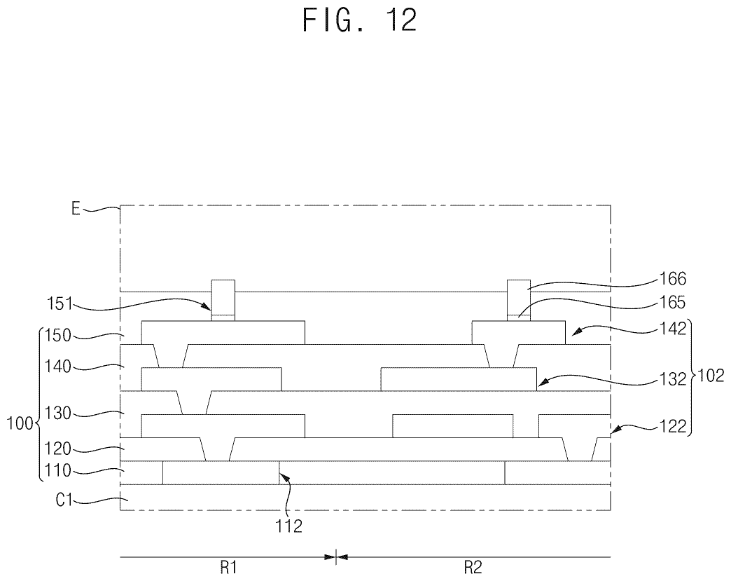

As illustrated in FIG. 12, an upper surface of the fifth lower insulating layer 150 may be partially removed to expose upper portions of the conductive pillars 166. The upper surface of the fifth lower insulating layer 150 may be removed by a plasma dry process. The plasma dry process may use an etching gas such as argon (Ar), oxygen (O2), etc.

As the upper surface of the fifth lower insulating layer 150 is partially removed, the upper portion of the conductive pillar 166 may protrude or extend from an opening 151 of the fifth lower insulating layer 150. Accordingly, the fifth lower insulating layer 150 may have the opening 151 that exposes a portion of the third lower redistribution wiring 142, and the conductive pillar 166 may be formed within the opening 151 of the fifth lower insulating layer 150.

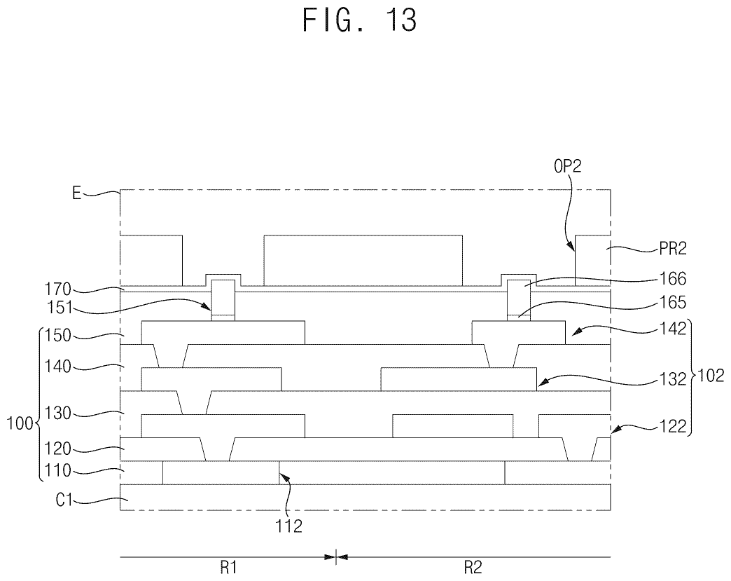

As illustrated in FIG. 13, a second seed layer 170 may be formed on the fifth lower insulating layer 150, and a second photoresist pattern PR2 having second openings OP2 that expose pad pattern regions may be formed on the second seed layer 170. The second openings may include third opening patterns that expose first pad pattern regions in the first region R1 and fourth opening patterns that expose second pad pattern regions in the second region R2.

The second seed layer 170 may be formed conformally along the upper surface of the fifth lower insulating layer 150 and the upper portion of the conductive pillar 166 that protrudes from the opening 151 of the fifth lower insulating layer 150. For example, the second seed layer may include copper, gold, silver, aluminum, or an alloy thereof. The second seed layer may be formed by a physical vapor deposition process or the like. The second seed layer may have a thickness of about 500 Å to about 1,500 Å.

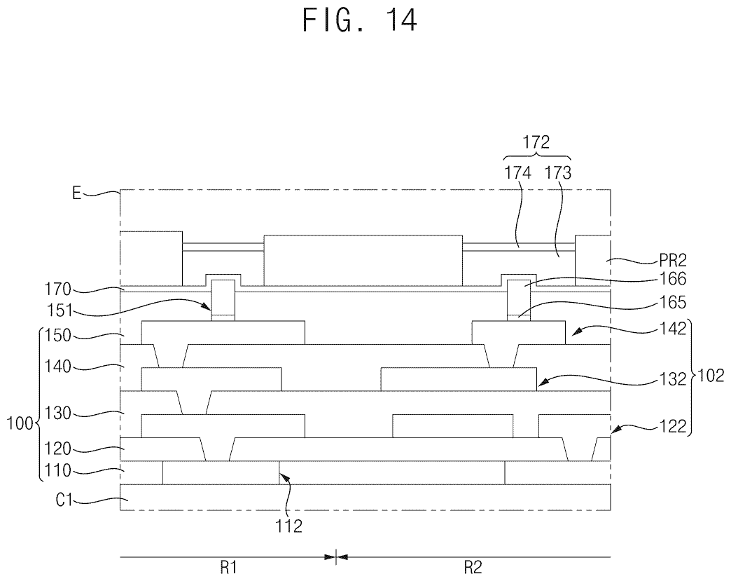

As illustrated in FIG. 14, an electrolytic plating process may be performed to form pad patterns 172 in the second openings OP2 of the second photoresist pattern PR2. The pad pattern 172 may be formed to at least partially surround the upper portion of the conductive pillar 166 that protrudes from the opening 151 of the fifth lower insulating layer 150. For example, a first plating process may be performed to form a first plating pattern 173 on the second seed layer 170, and a second plating process may be performed to form a second plating pattern 174 on the first plating pattern 173.

As illustrated in FIGS. 15 and 16, the second photoresist pattern PR2 may be removed by a strip process. Accordingly, the pad pattern 172 may be formed on the fifth lower insulating layer 150 to cover or overlap the upper surface of the conductive pillar 166. The pad pattern 172 may include the first plating pattern 173 and the second plating pattern 174 that are sequentially stacked. Then, an etching process may be performed to remove portions of the second seed layer 170 exposed by the pad pattern 172 to form a second seed layer pattern 171.

For example, the pad pattern 172 may have a second diameter D2 greater than the first diameter D1. The second diameter D1 may be in a range of 10 μm to 80 μm. A thickness of the first plating pattern 173 may be within a range of 2 μm to 8 μm. A thickness of the second plating pattern 174 may be within a range of 0.2 μm to 1 μm.

The first plating pattern 173 may include a material that acts as a diffusion barrier between a solder alloy and the conductive pillar 166 in a following soldering process. For example, the first plating pattern 173 may include nickel (Ni). The second plating pattern 174 may include a material for wetting with the solder material in the following soldering process. For example, the second plating pattern 174 may include gold (Au).

Accordingly, the upper bonding pads 162 including the conductive pillars 166 and pad patterns 172 that are sequentially stacked may be formed on the uppermost first redistribution wirings 142 located in the first region R1 and the second region R2 of the lower redistribution wiring layer 100. The pad pattern 172 may include the first plating pattern 173 and the second plating pattern 174 sequentially formed on the second seed layer pattern 171.

The upper bonding pads 162 may be exposed from an upper surface of the lower redistribution wiring layer 100. The upper bonding pads 162 may include the first bonding pads 162a as chip connection bonding pads formed on the uppermost first redistribution wirings 142 located in the first region R1, and the second bonding pads 162b as conductive structure connection bonding pads formed on the uppermost first redistribution wirings 142 located within the second region R2.

As described above, since the pad pattern 172 surrounds the protruding upper portion of the conductive pillar 166 including copper (Cu), the pad pattern 172 may be formed to have a flat or slightly convex top surface. Accordingly, when the second seed layer 170 under the pad pattern 172 is removed or wet etch rework is performed, a side surface of the conductive pillar 166 may be prevented from being etched. Accordingly, a uniform plating layer may be formed by the plating process of forming the pad pattern 172.

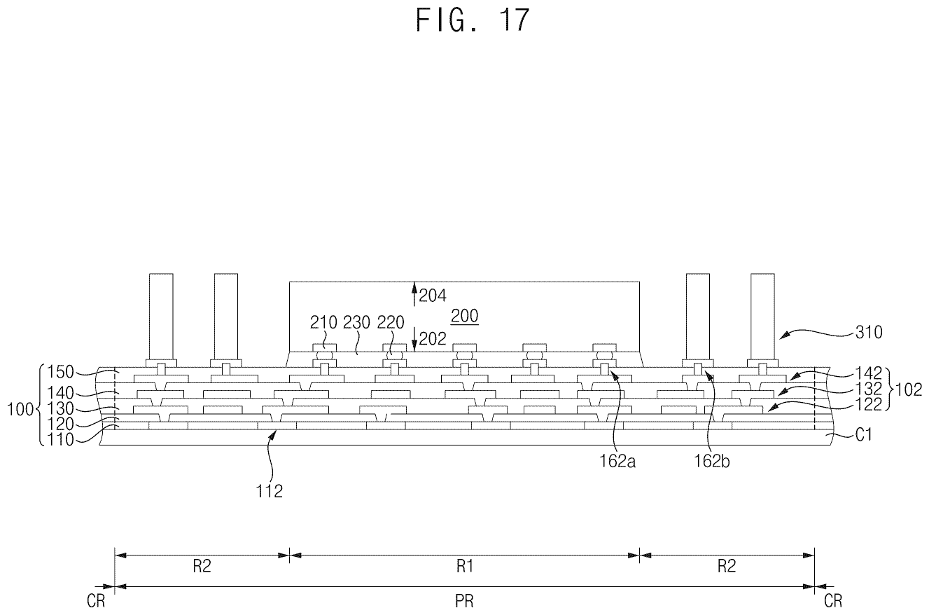

Referring to FIG. 17, a plurality of vertical conductive structures 310 may be formed in the second region R2 and at least one semiconductor chip 200 may be mounted in the first region R1 on the upper surface of the lower redistribution wiring layer 100.

In example embodiments, the plurality of vertical conductive structures 310 may be formed on the plurality of second bonding pads 162b located in the second region R2, respectively.

For example, a seed layer may be formed on the upper surface of the lower redistribution wiring layer 100 to cover or overlap the second bonding pads 162b, a photoresist pattern having openings that expose the vertical conductive structure regions may be formed on the seed layer, an electrolytic plating process may be performed on the seed layer to fill or be in the openings of the photoresist pattern with a conductive material to form the vertical conductive structures 310. Then, the photoresist pattern may be removed by a strip process, and portions of the seed layer exposed by the vertical conductive structures may be removed to form a seed layer pattern 302 (see FIG. 19).

Then, the semiconductor chip 200 may be disposed in the first region R1 as a fan-in region of the lower redistribution wiring layer 100. The semiconductor chip 200 may be mounted on the upper surface of the lower redistribution wiring layer 100 by a flip chip bonding method. The semiconductor chip 200 may be disposed such that a front surface 202 on which chip pads 210 are formed, that is, an active surface faces the lower redistribution wiring layer 100. The chip pads 210 of the semiconductor chip 200 may be electrically connected to the first redistribution wirings 102 of the lower redistribution wiring layer 100 by conductive bumps 220. The conductive bumps 220 may be bonded to the first bonding pads 162a on the uppermost first redistribution wirings 142, respectively. For example, the conductive bumps 220 may include micro bumps (uBumps). The conductive bump 220 may be bonded to the pad pattern 172 of the first bonding pad 162a.

An underfill member 230 may be underfilled between the semiconductor chip 200 and the lower redistribution wiring layer 100. The underfill member may include a material having relatively high fluidity to effectively fill or be in a small space between the semiconductor chip and the lower redistribution wiring layer. For example, the underfill member may include an adhesive containing an epoxy material.

The semiconductor chip may be a logic chip including a logic circuit. The logic chip may be a controller that controls memory chips. The semiconductor chip may be a processor chip such as an ASIC or an application processor (AP) serving as a host such as a CPU, GPU, or SOC.

As described above, since the pad pattern 172 at least partially surrounds the protruding upper portion of the conductive pillar 166, the pad pattern 172 may be formed to have a flat or slightly convex top surface. Accordingly, voids may be prevented or inhibited from occurring between the pad pattern 172 of the upper bonding pad 162 and the conductive bumps 220 or the vertical conductive structures 310 bonded to the pad pattern 172 of the upper bonding pad 162.

Referring to FIGS. 18 and 19, a molding member 400 may be formed on the upper surface of the lower redistribution wiring layer 100 to cover or overlap the semiconductor chip 200 and the plurality of the vertical conductive structures 310.

For example, the molding member 400 may include an epoxy molding compound (EMC). The molding member 400 may include UV resin, polyurethane resin, silicone resin, silica filler, etc.

The molding member 400 may include a first molding portion that covers or overlaps a backside surface 204 of the semiconductor chip 200, that is, an upper surface and a second molding portion that covers or overlaps the upper surface of the lower redistribution wiring layer 100 that at least partially surround the semiconductor chip 200.

The molding member 400 may include a first molding portion that covers or overlaps a backside surface 204 of the semiconductor chip 200, that is, an upper surface, and a second molding portion that covers the upper surface of the lower redistribution wiring layer 100 that at least partially surround the semiconductor chip 200. Upper surfaces of the vertical conductive structures 310 may be exposed by an upper surface 402 of the molding member 400.

Accordingly, the plurality of vertical conductive structures 310 may extend through the molding member 400 in the fan-out region R2 on the upper surface of the lower redistribution wiring layer 100. The vertical conductive structure 310 may function as a through mold via (TMV) formed through the second molding portion of the molding member 400.

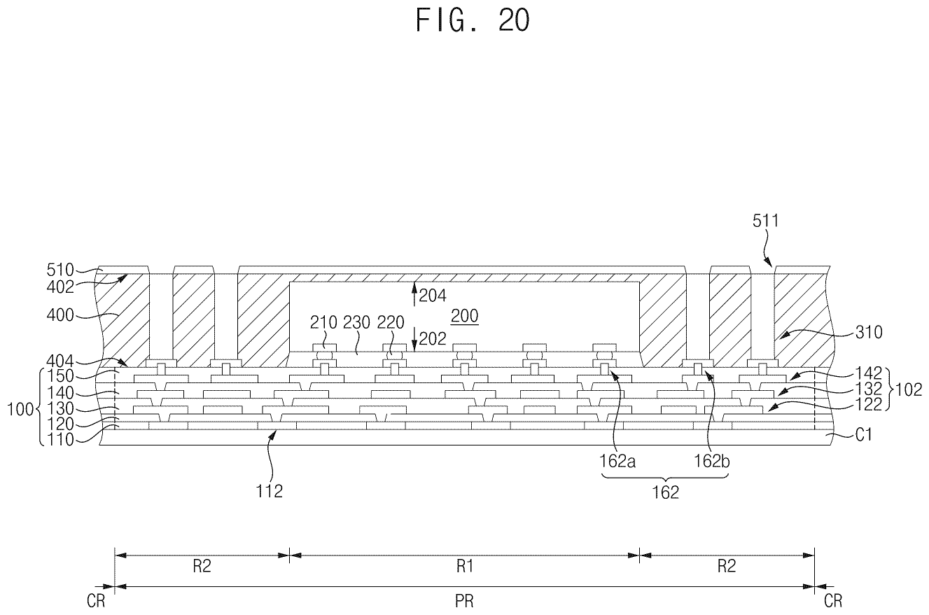

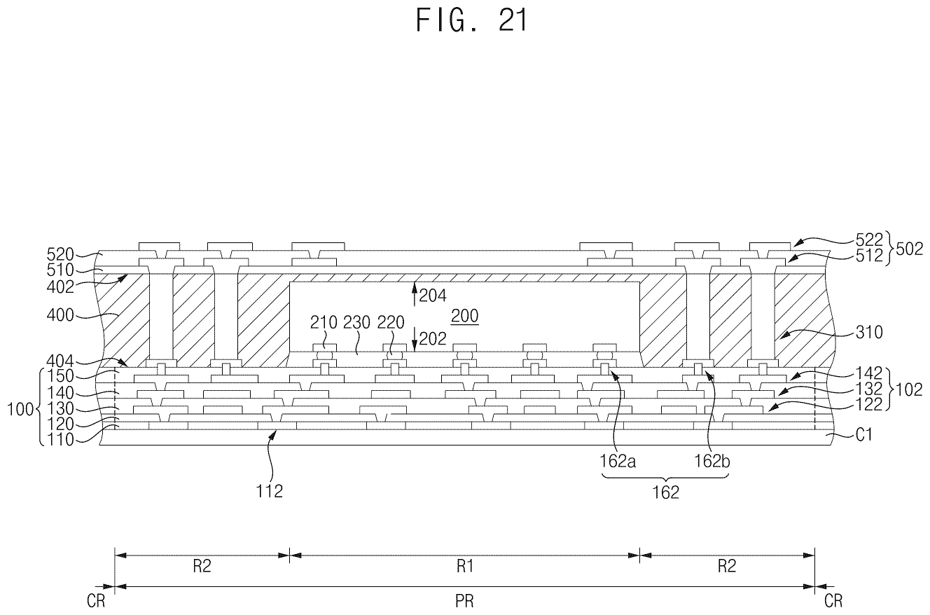

Referring to FIGS. 20 and 21, an upper redistribution wiring layer 500 having second redistribution wirings 502 electrically connected to the vertical conductive structures 310 may be formed on the upper surface 402 of the molding member 400.

As illustrated in FIG. 20, after a first upper insulating layer 510 is formed on the upper surface 402 of the molding member 400, the first upper insulating layer 510 may be patterned to form openings 511 that expose upper end portions of the vertical conductive structures 310 respectively. The first upper insulating layer 510 may include a polymer, a dielectric layer, etc. The first upper insulating layer 510 may be formed by a vapor deposition process, spin coating process, etc.

As illustrated in FIG. 21, after a seed layer is formed on the exposed upper end portions of the vertical conductive structures 310 and in the openings 511, the seed layer may be patterned and an electro plating process may be performed to form the first upper redistribution wirings 512. Accordingly, at least portions of the first upper redistribution wirings 512 may be electrically connected the upper end portions of the vertical conductive structures 310 through the openings 511. The first upper redistribution wiring may include aluminum (Al), copper (Cu), tin (Sn), nickel (Ni), gold (Au), platinum (Pt), or an alloy thereof.

Then, after a second upper insulating layer 520 is formed on the first upper insulating layer 510, the second upper insulating layer 520 may be patterned to form openings that expose the first upper redistribution wirings 512. Then, second upper redistribution wirings 522 may be formed on the second upper insulating layer 520 to directly contact the first upper redistribution wirings 512 through the openings of the second upper insulating layer 520.

Accordingly, the second redistribution wirings 502 may include the first upper redistribution wirings 512 and the first upper redistribution wiring 522 that are stacked to form at least two layers. In this case, the first upper redistribution wiring 512 may correspond to a lowermost redistribution wiring among the second redistribution wirings, and the second upper redistribution wiring 522 may correspond to an uppermost redistribution wiring among the second redistribution wirings.

Referring to FIGS. 22 and 23, processes the same as or similar to the processes described with reference to FIGS. 6 to 16 may be performed to form upper bonding pads 562 on the second upper redistribution wirings 522 as the uppermost redistribution wirings respectively.

In example embodiments, a conductive pillar 566 may be formed on the second upper redistribution wiring 522 as the uppermost redistribution wiring, and a third upper insulating layer 530 as a protective layer may be formed on the second upper insulating layer 520 to exposed an upper portion of the conductive pillar 566. Then, a pad pattern 572 may be formed on the third upper insulating layer 530 to cover or overlap the exposed upper portion of the conductive pillar 566. The pad pattern 572 may include a first plating pattern 573 and a second plating pattern 574 that are sequentially stacked.

In particular, a third seed layer may be formed on the second upper insulating layer 520, and a third photoresist pattern having third openings that expose conductive pillar regions may be formed on the third seed layer. An electrolytic plating process may be performed to form the conductive pillars 566 in the third openings of the third photoresist pattern. The third photoresist pattern may be removed by a strip process, and an etching process may be performed to remove portions of the third seed layer exposed by the conductive pillars 566 to form a third seed layer pattern 565.

Then, the third upper insulating layer 530 may be formed on the second upper insulating layer 520 to cover or overlap the second upper redistribution wirings 522 and the conductive pillars 566. For example, the third upper insulating layer 530 may include an insulating material such as a photosensitive insulating material (PID). Then, an upper surface of the third upper insulating layer 530 may be partially removed to expose the upper portions of the conductive pillars 566.

Then, a fourth seed layer may be formed on the third upper insulating layer 530, and a fourth photoresist pattern having fourth openings that exposing pad pattern regions may be formed on the fourth seed layer. An electrolytic plating process may be performed to form the pad patterns 572 in the fourth openings of the fourth photoresist pattern. A first plating process may be performed to form the first plating pattern 573 on the fourth seed layer, and a second plating process may be performed to form the second plating pattern 574 on the first plating pattern 573.

Then, the fourth photoresist pattern may be removed through a strip process. Accordingly, the pad pattern 572 may be formed on the third upper insulating layer 530 to cover or overlap the upper surface of the conductive pillar 166. The pad pattern 572 may include the first plating pattern 573 and the second plating pattern 574 that are sequentially stacked. Then, an etching process may be performed to remove portions of the fourth seed layer exposed by the pad pattern 572 to form a fourth seed layer pattern 571.

Thus, the second redistribution wiring layer 500 as a backside redistribution wiring layer (BRDL) having the second redistribution wirings 502 may be formed on the molding member 400. The second redistribution wiring layer 500 may include the first to third upper insulating layer 510, 520 and 530 sequentially stacked and the second redistribution wirings 502 within the stacked first to third upper insulating layers 510, 520 and 530. The second redistribution wirings 502 may include the first and second upper redistribution wirings 512 and 522.

It will be understood that the number, size, and arrangement of the upper insulating layers and the upper redistribution wirings of the second redistribution wiring layer are provided as examples, and the present disclosure is not limited thereto.

Then, the carrier substrate C1 may be removed, and external connection members 600 (see FIG. 1) may be formed on the lower bonding pads 112 on a lower surface of the lower redistribution wiring layer 100.

Then, a sawing process may be performed to individualize the lower redistribution wiring layers 100 to complete the fan out wafer level package (e.g., the semiconductor package 10 of FIG. 1) including the molding member 400, the lower redistribution wiring layer 100 formed on a lower surface 404 of the molding member 400 and the upper redistribution wiring layer 500 formed on the upper surface 402 of the molding member 400.

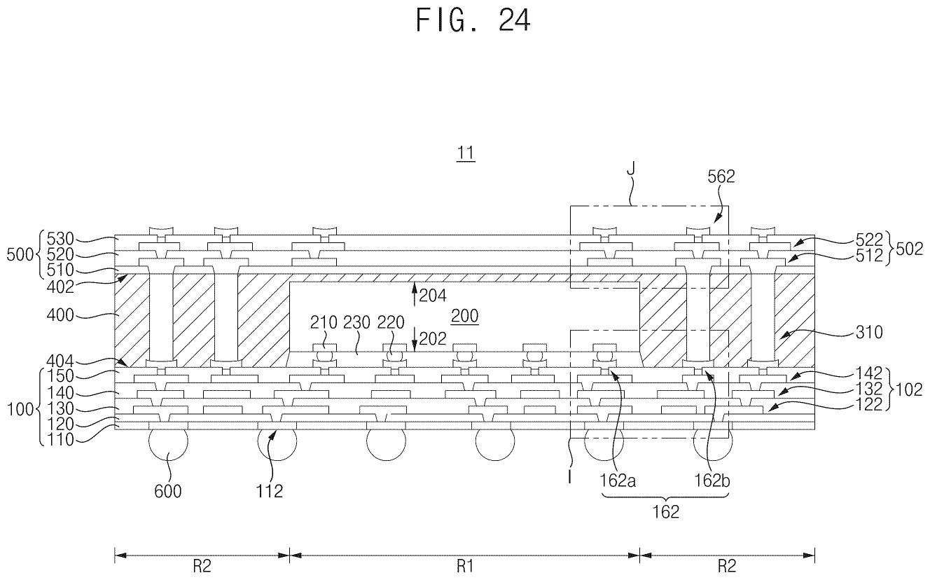

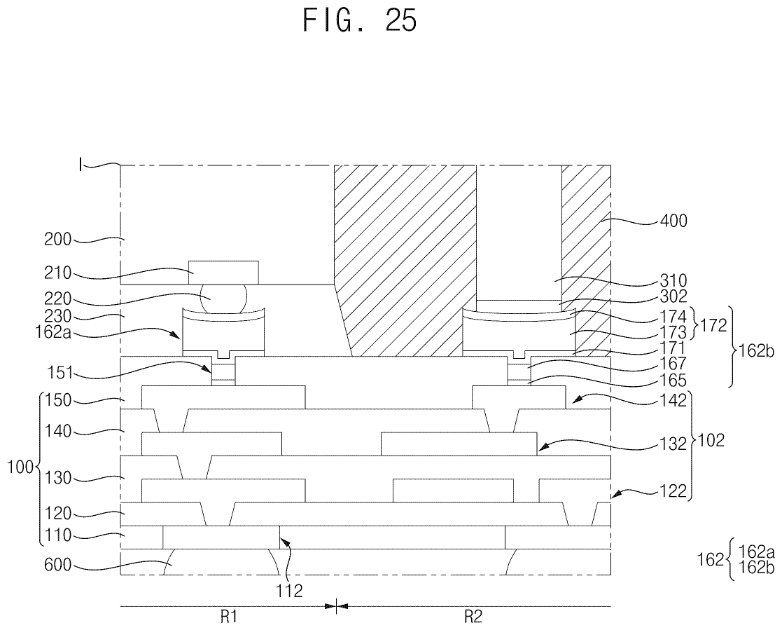

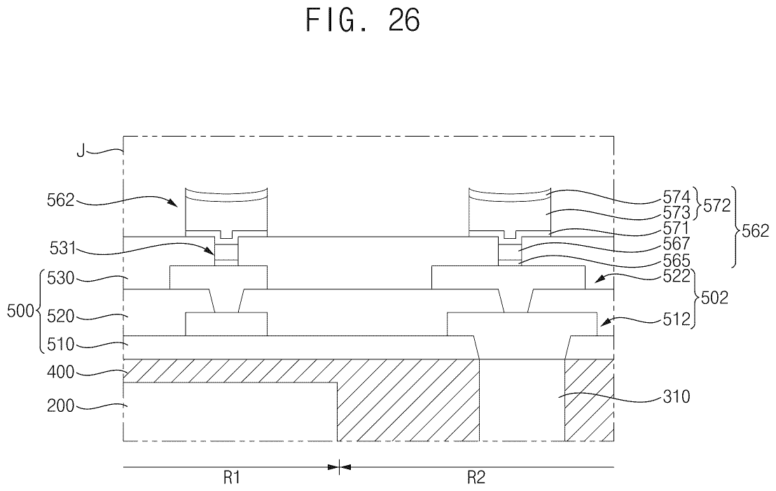

FIG. 24 is a cross-sectional view illustrating a semiconductor package in accordance with example embodiments. FIG. 25 is an enlarged cross-sectional view illustrating portion ‘I’ in FIG. 24. FIG. 26 is an enlarged cross-sectional view illustrating portion ‘J’ in FIG. 24. The semiconductor package may be substantially the same as the semiconductor package described with reference to FIGS. 1 to 3 except for configurations of upper bonding pads. Thus, same reference numerals may be used to refer to the same or like elements and any further repetitive explanation concerning the above elements will be omitted.

Referring to FIGS. 24 to 26, a semiconductor package 11 may include a lower redistribution wiring layer 100, a semiconductor chip 200, a molding member 400, vertical conductive structures 310, and an upper redistribution wiring layer 500. The lower redistribution wiring layer 100 may include first redistribution wirings 102, a protective layer 150 having openings 151 that expose at least portions of uppermost redistribution wirings 142 among the first redistribution wirings 102, and upper bonding pads 162 provided on the protective layer 150 and electrically connected to the uppermost redistribution wirings 142 through the openings 151.

As illustrated in FIG. 25, in example embodiments, each of the upper bonding pads 162 may include a second conductive pillar 167 provided in the opening 151 of the protective layer 150 on the uppermost redistribution wiring 142 and a pad pattern 172 provided on the protective layer 150 to cover an upper surface of the second conductive pillar 166.

The second conductive pillar 167 may fill a portion of the opening 151. The upper surface of the second conductive pillar 167 may be lower than an upper surface of the protective layer 150, that is, fifth lower insulating layer. The pad pattern 172 may be formed to cover or overlap the upper surface of the second conductive pillar 167 within the opening 151 of the fifth lower insulating layer 150. The pad pattern 172 may completely fill the opening 151 on the second conductive pillar 167.

The second conductive pillar 167 including copper (Cu) may partially fill or be in the opening 151 and the pad pattern 172 may completely fill or be in the opening 151 on the second conductive pillar 167, and accordingly, the pad pattern 172 may be formed to have a slightly concave upper surface corresponding to the portion that fills or is in the opening 151, that is, a nonlinear shape (e.g., a dishing/dish shape).

Accordingly, it may be possible to prevent or inhibit voids from occurring between the pad pattern 172 of the upper bonding pad 162 and the conductive bumps 220 or the vertical conductive structure 310 bonded to the pad pattern 172 of the upper bonding pad 162.

As illustrated in FIG. 26, upper bonding pads 562 may be provided on second upper redistribution wirings 522 as uppermost redistribution wirings, respectively. A third upper insulating layer 530 as a protective layer may be formed on a second upper insulating layer 520 and may have openings 531 that expose portions of the second upper redistribution wirings 522. Each of the upper bonding pads 562 may have a second conductive pillar 567 provided in the opening 531 of the protective layer 530 on the uppermost redistribution wiring 522 and a pad pattern 572 provided on the protective layer 530 to cover or overlap an upper surface of the second conductive pillar 567.

The second conductive pillar 567 may partially fill or be in the opening 531. The upper surface of the second conductive pillar 567 may be lower than an upper surface of the third upper insulating layer 530. The pad pattern 572 may be formed to cover or be in the upper surface of the second conductive pillar 567 within the opening 531 of the third upper insulating layer 530. The pad pattern 572 may completely fill or be in the opening 531 on the second conductive pillar 567.

The second conductive pillar 567 including copper (Cu) may partially fill or be in the opening 531 and the pad pattern 572 may completely fill or be in the opening 531 on the second conductive pillar 567, and accordingly, the pad pattern 572 may be formed to have a slightly concave upper surface corresponding to the portion that fills or is in the opening 531, that is, a nonlinear shape (e.g., a dishing/dish shape).

Hereinafter, a method of manufacturing the semiconductor package of FIG. 24 will be described.

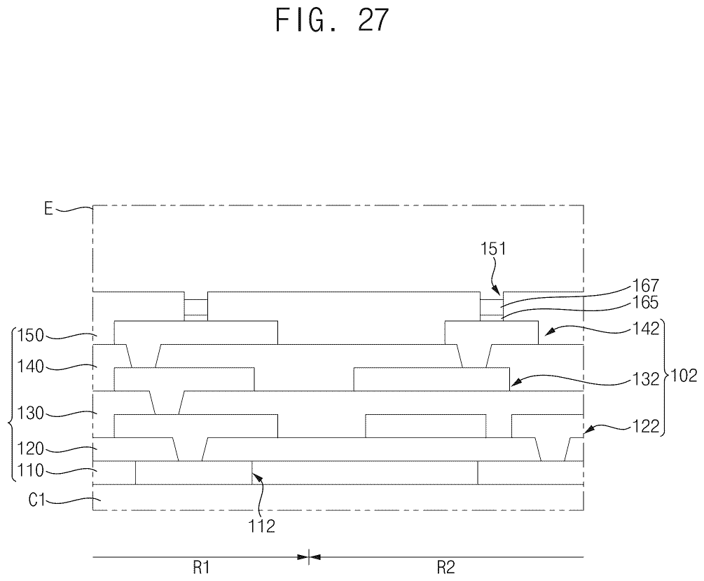

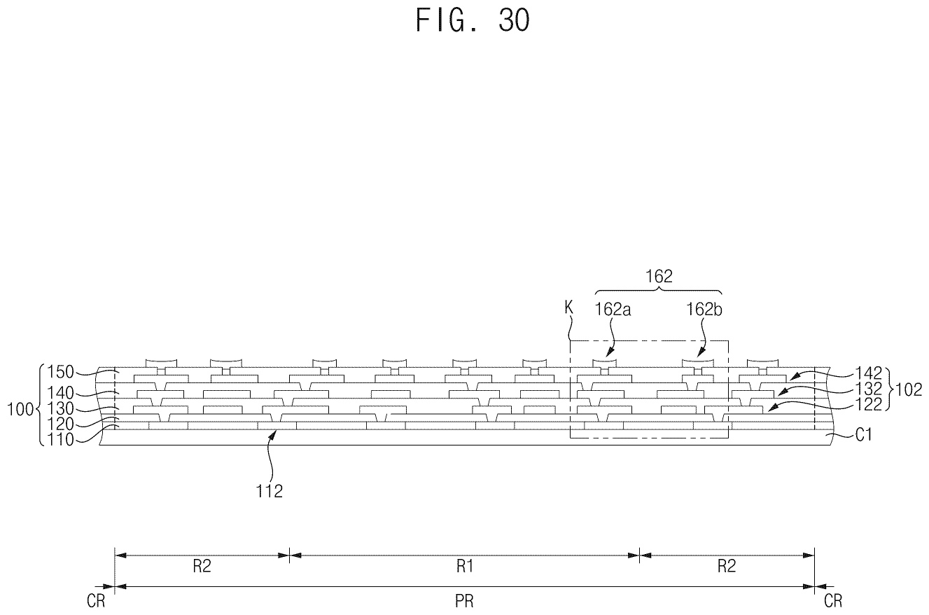

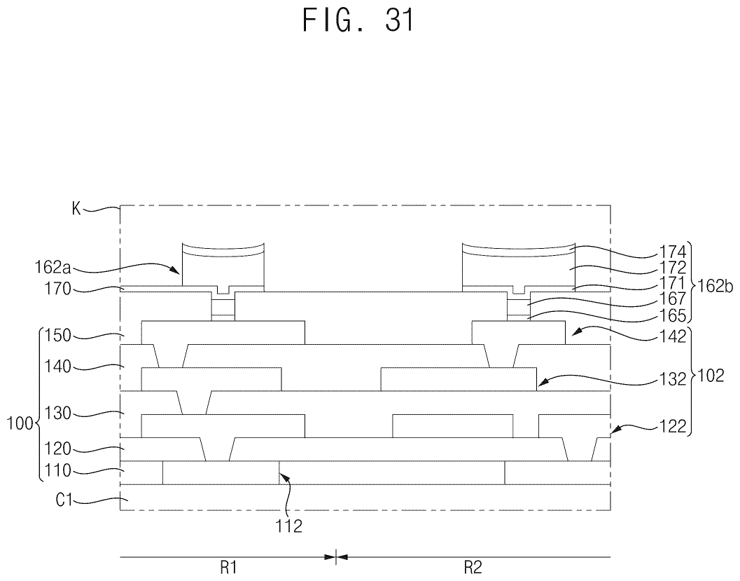

FIGS. 27 to 31 are cross-sectional views illustrating a method of manufacturing a semiconductor package in accordance with example embodiments. FIGS. 27 to 29 are enlarged cross-sectional views illustrating portion ‘E’ of FIG. 12. FIG. 31 is an enlarged cross-sectional view illustrating portion ‘K’ in FIG. 30.

Referring to FIGS. 27 to 31, upper bonding pads 162 may be formed on third lower redistribution wirings 142 as uppermost redistribution wirings among first redistribution wirings 102 of a lower redistribution wiring layer 100.

As illustrated in FIG. 27, first, processes the same as or similar to the processes described with reference to FIGS. 6 to 12 may be performed to form a conductive pillar 166 on the third lower redistribution wiring 142 and to form a fifth lower insulating layer 150 as a protective layer having an opening 151 that exposes an upper portion of the conductive pillar 166 on a fourth lower redistribution wiring layer 140, and an upper portion of the conductive pillar 166 may be partially removed to form a second conductive pillar 167 that partially fill the opening 151.

For example, a wet etching process may be performed to selectively remove only the upper portion of the conductive pillar 166 that is exposed from the opening 151 of the fifth lower insulating layer 150. The wet etching process may use a wet solution containing sulfuric acid and hydrogen peroxide.

As the upper portion of the conductive pillar 166 is partially removed, a height of the second conductive pillar 167 within the opening 151 may be reduced. An upper surface of the second conductive pillar 167 may be lower than an upper surface of the fifth lower insulating layer 150. The height of the second conductive pillar 167 may be determined by the progress time of the wet etching process.

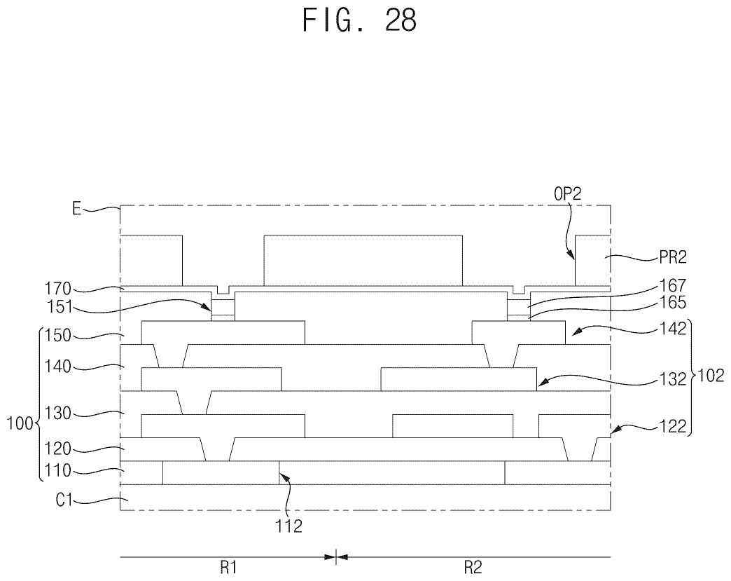

As illustrated in FIG. 28, a second seed layer 170 may be formed on the fifth lower insulating layer 150, and a second photoresist pattern PR2 having second openings OP2 that expose pad pattern regions may be formed on the second seed layer 170.

The second seed layer 170 may be formed conformally along the upper surface of the fifth lower insulating layer 150 and the upper surface of the second conductive pillar 167 within the opening 151 of the fifth lower insulating layer 150.

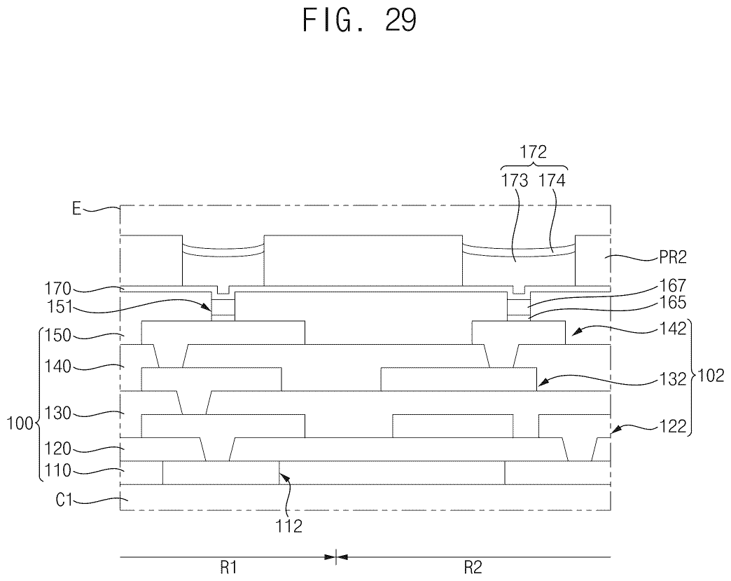

As illustrated in FIG. 29, pad patterns 172 may be formed in the second openings OP2 of the second photoresist pattern PR2 by performing an electrolytic plating process. The pad pattern 172 may be formed to cover or overlap the upper surface of the second conductive pillar 167 within the opening 151 of the fifth lower insulating layer 150. The pad pattern 172 may completely fill or be in the opening 151 on the second conductive pillar 167.

As illustrated in FIGS. 30 and 31, the second photoresist pattern PR2 may be removed by a strip process. Accordingly, the pad pattern 172 may be formed to cover or overlap the upper surface of the second conductive pillar 167 on the fifth lower insulating film 150. The pad pattern 172 may include a first plating pattern 173 and a second plating pattern 174 that are sequentially stacked. Then, an etching process may be performed to remove portions of the second seed layer 170 exposed by the pad pattern 172 to form a second seed layer pattern 171.

The second conductive pillar 167 including copper (Cu) may partially fill or be in a portion of the opening 151 and the pad pattern 172 may completely fill or be in the opening 151 on the second conductive pillar 167, and accordingly, the pad pattern 172 may be formed to have a slightly concave upper surface corresponding to the portion that fills or is in the opening 151, that is, a nonlinear shape (e.g., a dishing/dish shape).

Then, processes the same as or similar to the processes described with reference to FIGS. 17 to 23 may be performed to form the semiconductor package 11 in FIG. 24.

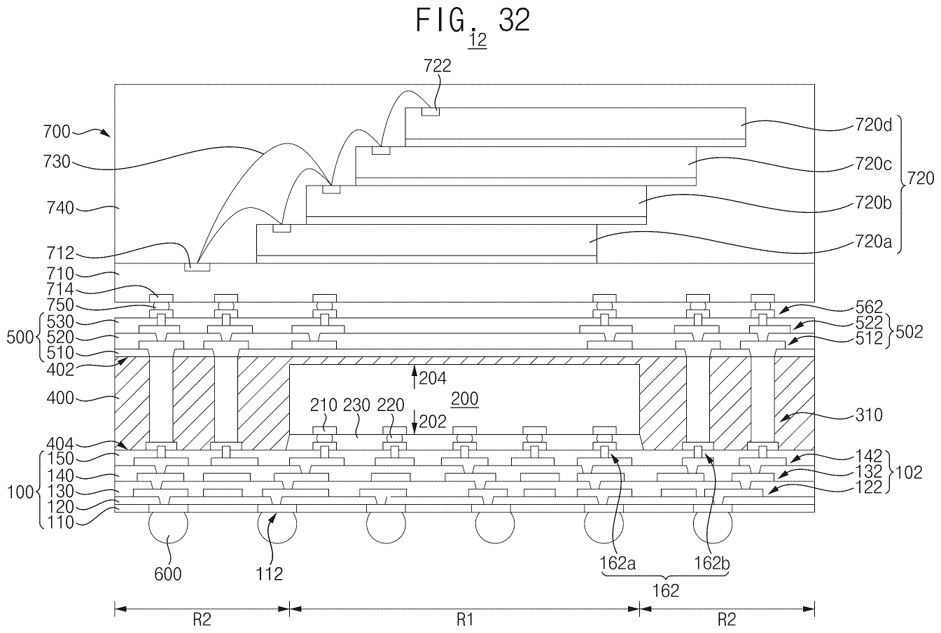

FIG. 32 is a cross-sectional view illustrating a semiconductor package in accordance with example embodiments. The semiconductor package may be substantially the same as the semiconductor package described with reference to FIGS. 1 to 3 except for an additional second package. Thus, same reference numerals may be used to refer to the same or like elements and any further repetitive explanation concerning the above elements will be omitted.

Referring to FIG. 32, a semiconductor package 12 may include a first package and a second package 700 stacked on the first package. The first package may include a lower redistribution wiring layer 100, a semiconductor chip 200, a plurality of conductive vertical structures 310, a molding member 400 and an upper redistribution wiring layer 500. The first package may be substantially the same as or similar to the unit package described with reference to FIG. 1.

In example embodiments, the second package 700 may include a second package substrate 710, a plurality of second semiconductor chips 720 mounted on the second package substrate 710 and a molding member 740 covering or overlapping the second semiconductor chips 720 on the second package substrate 710.

The second package 700 may be stacked on the first package via conductive connection members 750. For example, the conductive connection members 750 may include solder balls, conductive bumps, etc. The conductive connection member 750 may be disposed between an upper bonding pad on a third upper redistribution wiring 522 of the upper redistribution wiring layer 500 and a second connection pad 714 of the second package substrate 710. Accordingly, the first package and the second package 700 may be electrically connected to each other by the conductive connection members 750.

A plurality of second semiconductor chips 720a, 720b, 720c and 720d may be sequentially stacked on the second package substrate 710 by adhesive members. Bonding wires 730 may connect second chip pads 722 of the second semiconductor chips 720 to first connection pads 712 of the second package substrate 710. The second semiconductor chips 720 may be electrically connected to the second package substrate 710 by the bonding wires 730.

Although the second package 700 includes four semiconductor chips mounted by a wire bonding method, it will be understood that the number of the semiconductor chips in the second package and the mounting method are not limited thereto.

In example embodiments, the semiconductor package 12 may further include a heat sink (not illustrated) stacked on the second package 700. The heat sink may be provided on the second package 700 to dissipate heat from the first and second packages to the outside. The heat sink may be attached on the second package 700 by a thermal interface material (TIM).

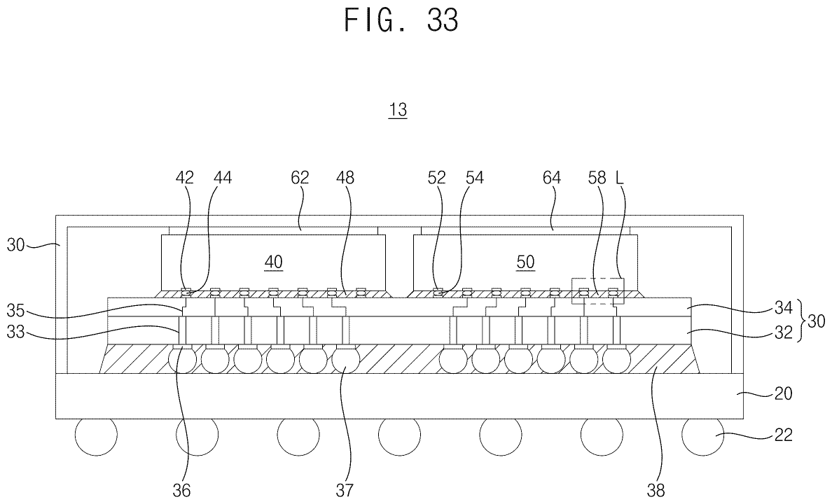

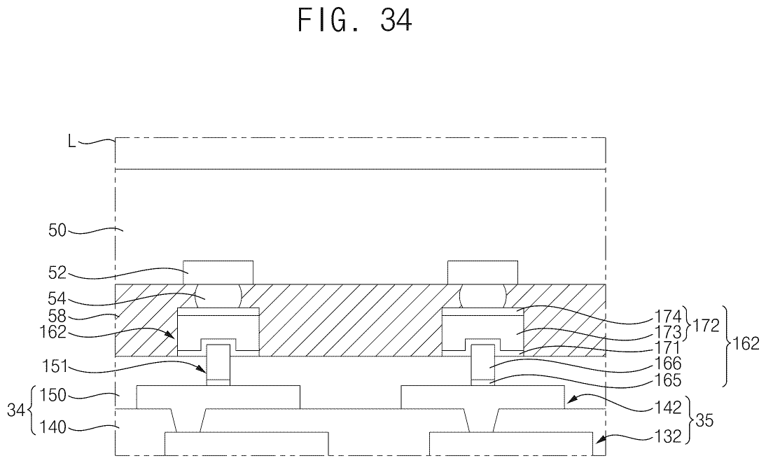

FIG. 33 is a cross-sectional view illustrating a semiconductor package in accordance with example embodiments. FIG. 34 is an enlarged cross-sectional view illustrating portion ‘L’ in FIG. 33. The semiconductor package may be substantially the same as the semiconductor package described with reference to FIG. 1 except for a configuration of 2.5D semiconductor package. Thus, same reference numerals may be used to refer to the same or like elements and any further repetitive explanation concerning the above elements will be omitted.

Referring to FIGS. 33 and 34, a semiconductor package 13 may include a substrate 20, an interposer 30, a first semiconductor device 40 and a second semiconductor device 50. Additionally, the semiconductor package 13 may further include first and second underfill members 38, 48 and 58 and a heat slug 60.

In example embodiments, the semiconductor package 13 may be a memory device having a stacked chip structure in which a plurality of dies (e.g., chips) are stacked. For example, the semiconductor package 13 may include a semiconductor memory device with a 2.5D chip structure. The semiconductor package 13 including the memory device of the 2.5D chip structure may include the interposer 30 as a redistribution wiring layer for electrically connecting the first and second electronic devices 40 and 50.

In this case, the first semiconductor device 40 may include a logic semiconductor device, and the second semiconductor device 50 may include a memory device. The logic semiconductor device may include a CPU, a GPU, an ASIC, or an SOC. The memory device may include a high bandwidth memory (HBM) device.

In example embodiments, the substrate 20 may have an upper surface and a lower surface opposite to each other. For example, the substrate 20 may be a printed circuit board (PCB). The PCB may be a multilayered circuit board including vias and various circuits therein.

The interposer 30 may be disposed on the substrate 20. A planar area of the interposer 30 may be less than a planar area of the substrate 20. The interposer 30 may be disposed within the area of the substrate 20 in plan view.

The interposer 30 may be a silicon interposer or redistribution wiring interposer including a plurality of redistribution wirings 35 therein. The first semiconductor device 40 and the second semiconductor device 50 may be connected to each other through the redistribution wirings and may be electrically connected to the substrate 20 through solder bumps 37. The silicon interposer may provide a high density interconnection between the first and second semiconductor devices 40 and 50.

In example embodiments, the interposer 30 may include a semiconductor substrate 32, a wiring layer 34 including a plurality of redistribution wirings 35 on an upper surface of the substrate 20, a plurality of upper bonding pads 162 provided on the wiring layer 34 and having a plurality of lower bonding pads 36 provided on a lower surface of the semiconductor substrate 20.

As illustrated in FIG. 34, the interposer 30, which may be the redistribution wiring layer, may include redistribution wirings 35 and a protective layer 150 having openings 151 that expose at least portions of uppermost redistribution wirings 142 among the redistribution wirings 35, and the upper bonding pads 162 provided on the protective layer 150 and electrically connected to the uppermost redistribution wirings 142 through the openings 151.

Each of the upper bonding pads 162 may include a second conductive pillar 167 provided in the opening 151 of the protective layer 150 on the uppermost redistribution wiring 142 and a pad pattern 172 provided on the protective layer 150 to cover or overlap an upper surface of the second conductive pillar 166.

The second conductive pillar 167 may protrude or extend from the opening 151. The pad pattern 172 may be provided on the fifth lower insulating layer 150 to at least partially surround the upper portion of the conductive pillar 166 that protrudes or extends from the opening 151 of the fifth lower insulating layer 150. Since the pad pattern 172 surrounds the protruding upper portion of the conductive pillar 166, the pad pattern 172 may be formed to have a flat or convex upper surface. The upper bonding pad 162 may further include a second seed layer pattern 171 that conformally covers or overlaps the upper portion of the conductive pillar 166 that is exposed from the opening 151 on the fifth lower insulating layer 150, and the pad pattern 172 may be formed on the second seed layer pattern 171. The pad pattern 172 may include a first plating pattern 173 and a second plating pattern 174 that are sequentially stacked.

Alternatively, the second conductive pillar 167 may partially fill or be in the opening 151 of the fifth lower insulating layer 150. The upper surface of the second conductive pillar 167 may be lower than an upper surface of the fifth lower insulating layer 150. The pad pattern 172 may be formed to cover or overlap the upper surface of the second conductive pillar 167 within the opening 151 of the fifth lower insulating layer 150. The pad pattern 172 may completely fill or be in the opening 151 on the second conductive pillar 167. The second conductive pillar 167 including copper (Cu) may partially fill or be in the opening 151 and the pad pattern 172 may completely fill or be in the opening 151 on the second conductive pillar 167, and accordingly, the pad pattern 172 may be formed to have a slightly concave upper surface corresponding to the portion that fills or is in the opening 151, that is, a nonlinear shape (e.g., a dishing/dish shape).

In example embodiments, the first semiconductor device 40 may be arranged on the interposer 30. The first semiconductor device 40 may be mounted on the interposer 30 in a flip chip boding manner. In this case, the first semiconductor device 40 may be mounted such that an active surface of the first semiconductor device 40 on which chip pads 42 are formed face the interposer 30. The chip pads 42 of the first semiconductor device 40 may be electrically connected to the bonding pads 162 of the interposer 30 by conductive bumps 44. For example, the conductive bumps 44 may include micro bump (uBump).

The second semiconductor device 50 may be arranged on the interposer 30 to be spaced apart from the first semiconductor device 40. The second semiconductor device 50 may be mounted on the interposer 30 in a flip chip boding manner. In this case, the second semiconductor device 50 may be mounted such that an active surface of the second semiconductor device 50 on which chip pads 52 are formed face the interposer 30. The chip pads 52 of the second semiconductor device 50 may be electrically connected to the bonding pads 162 of the interposer 30 by conductive bumps 54. For example, the conductive bumps 54 may include micro bump (uBump).

Although only one first semiconductor device 40 and one second semiconductor device 50 are illustrated in the figures, the numbers and arrangements thereof are exemplary, and it may not be limited thereto.

In example embodiments, the semiconductor package 10 may further include a first adhesive 290 underfilled between the interposer 30 and the package substrate 20, a second adhesive 350 underfilled between the first semiconductor device 40 and the interposer 30, and a third adhesive 450 underfilled between the second semiconductor device 40 and the interposer 20.

For example, the first underfill members 48, 58 may be underfilled between the first semiconductor devices 40 and 50 and the interposer 30. The second underfill member 38 may be underfilled between the interposer 30 and the substrate 20.

The first and second underfill members may include a material having relatively high fluidity to effectively fill or be in small spaces between the first and second semiconductor devices and the interposer and between the interposer and the substrate. For example, the first and second underfill members may include an adhesive containing an epoxy material.

The second semiconductor device 50 may include a buffer die and a plurality of memory dies (chips) sequentially stacked on the buffer die. The buffer die and the memory dies may be electrically connected to each other by through silicon vias (TSVs).

In example embodiments, the heat slug 60 may cover or overlap the first and second semiconductor devices 40 and 50 on the substrate 20 to be in thermal contact with the first and second semiconductor devices 40 and 50. Thermal interface materials (TIM) 62, 64 may be provided on upper surfaces of the first and second semiconductor devices 40 and 50, respectively. The heat slug 60 may be placed in thermal contact with the first and second semiconductor devices 40 and 50 via the thermal interface materials 62, 64.

Outer connection pads may be formed on a lower surface of the substrate 20, and outer connection members 22 for an electrical connection with an external device may be disposed on the outer connection pads. The outer connection members 22 may be, for example, solder balls. The semiconductor package 13 may be mounted on a module substrate via the solder balls, to constitute a memory module.

As mentioned above, the pad pattern 172 of the upper bonding pad 162 of the interposer 30 at least partially surrounds the protruding upper portion of the conductive pillar 166 including copper (Cu), so the pad pattern 172 may have a flat or slightly convex upper surface. Accordingly, when the seed layer under the pad pattern 172 is removed or wet etch rework is performed, a side surface of the conductive pillar 166 may be prevented or inhibited from being etched. Further, voids may be prevented or inhibited from occurring between the pad pattern 172 of the upper bonding pad 162 and the conductive bumps 44 and 54 bonded to the pad pattern 172 of the upper bonding pad 162.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present disclosure. Accordingly, all such modifications are intended to be included within the scope of example embodiments as defined in the claims.

1. A semiconductor package, comprising:
a lower redistribution wiring layer that comprises first redistribution wirings, a protective layer that defines openings, and bonding pads that are on the protective layer and are electrically connected to the first redistribution wirings through the openings;
conductive bumps that are on first bonding pads of the bonding pads; and
a semiconductor chip on the first bonding pads,
wherein each of the bonding pads comprises:
a conductive pillar in a respective opening of the openings of the protective layer, wherein the conductive pillar comprises a first diameter; and
a pad pattern that is on the protective layer and an upper surface of the conductive pillar, wherein the pad pattern comprises a second diameter that is greater than the first diameter.

2. The semiconductor package of claim 1, wherein the conductive pillar extends from the respective opening, and wherein the pad pattern at least partially surrounds an upper portion of the conductive pillar.

3. The semiconductor package of claim 1, wherein the conductive pillar is partially in the respective opening, and wherein the pad pattern is completely in the respective opening.

4. The semiconductor package of claim 1, wherein the first diameter is in a range of about 5 μm to 50 μm, and the second diameter is in a range of about 10 μm to 80 μm.

5. The semiconductor package of claim 1, wherein the conductive pillar comprises copper.

6. The semiconductor package of claim 1, wherein the bonding pad further comprises a seed layer pattern that is on the conductive pillar, and wherein the pad pattern is on the seed layer pattern.

7. The semiconductor package of claim 6, wherein the pad pattern further comprises a first plating pattern on the seed layer pattern and a second plating pattern on the first plating pattern.

8. The semiconductor package of claim 1, further comprising:
a molding member that is on the semiconductor chip and the lower redistribution wiring layer; and
a plurality of vertical conductive structures that extend into the molding member and at least partially surround the semiconductor chip.

9. The semiconductor package of claim 8, wherein the plurality of vertical conductive structures are on respective second bonding pads of the bonding pads.

10. The semiconductor package of claim 8, further comprising an upper redistribution wiring layer that is on the molding member and comprises second redistribution wirings that are electrically connected to the plurality of vertical conductive structures.

11. A semiconductor package, comprising:
a lower redistribution wiring layer that comprises:
a first region and a second region that at least partially surrounds the first region,
first redistribution wirings, and
a protective layer that defines first openings;
a plurality of first bonding pads that are in the first region, on the protective layer, and electrically connected to the first redistribution wirings through the first openings; and
a semiconductor chip that is on the first region of the lower redistribution wiring layer and electrically connected to the first bonding pads, wherein the semiconductor chip comprises chip pads that face the lower redistribution wiring layer,
wherein each of the first bonding pads includes:
a conductive pillar in a respective first opening of the first openings of the protective layer; and
a pad pattern that is on the protective layer and a portion of the conductive pillar.

12. The semiconductor package of claim 11, wherein the conductive pillar extends from the respective first opening, and wherein the pad pattern at least partially surrounds an upper portion of the conductive pillar.

13. The semiconductor package of claim 11, wherein the conductive pillar is partially in the respective first opening, and the pad pattern is completely in the respective first opening.

14. The semiconductor package of claim 11, wherein the conductive pillar comprises a first diameter, and wherein the pad pattern comprises a second diameter that is greater than the first diameter.

15. The semiconductor package according to claim 11, wherein each of the first bonding pads further comprises a seed layer pattern that is on the conductive pillar.

16. The semiconductor package of claim 15, wherein the pad pattern further comprises a first plating pattern on the seed layer pattern and a second plating pattern on the first plating pattern.

17. The semiconductor package of claim 11, further comprising conductive bumps that are on the chip pads and the plurality of first bonding pads.

18. The semiconductor package of claim 11, further comprising:
a plurality of second bonding pads that are in the second region, on the protective layer, and electrically connected to the first redistribution wirings through the first openings;
a molding member that is on the semiconductor chip and on the second region of the lower redistribution wiring layer;
a plurality of vertical conductive structures that extend into the molding member, wherein the plurality of vertical conductive structures are respectively on the plurality of second bonding pads; and
an upper redistribution wiring layer that is on the molding member and comprises second redistribution wirings that are electrically connected to the plurality of vertical conductive structures.

19. The semiconductor package of claim 18, wherein:
the upper redistribution wiring layer comprises a second protective layer that defines second openings, wherein the upper redistribution wiring layer comprises upper bonding pads that are on the second protective layer and are electrically connected to the second redistribution wirings through the second openings, and
each of the upper bonding pads includes:
a conductive pillar in a respective second opening of the second openings of the second protective layer; and
a pad pattern that is on the second protective layer and on a portion of the conductive pillar.

20. A semiconductor package, comprising:
a redistribution wiring layer that comprises redistribution wirings, a protective layer that defines openings, and bonding pads that are on the protective layer and are electrically connected to the redistribution wirings through the openings;
conductive bumps on the bonding pads; and
a first semiconductor device and a second semiconductor device that are spaced apart from each other on the redistribution wiring layer and are on the conductive bumps,
wherein each of the bonding pads includes:
a conductive pillar in a respective opening of the openings of the protective layer, the conductive pillar comprising a first diameter; and
a pad pattern that is on the protective layer and an upper surface of the conductive pillar, wherein the pad pattern comprises a second diameter that is greater than the first diameter.

21-30. (canceled)
